(19) United States
(12) Patent Application Publication
(10) Pub. No.: US 2024/0096591 A1
(43) Pub. Date: Mar. 21, 2024

(54) NON-DESTRUCTIVE SEM-BASED DEPTH-PROFILING OF SAMPLES

(71) Applicant: APPLIED MATERIALS ISRAEL LTD., Rehovot (IL)

(72) Inventors: Dror Shemesh, Hod Hasharon (IL); Doron Girmonsky, Raanana (IL); Uri Hadar, Tel-Aviv (IL); Michal Eilon, Beit-Elazari (IL)

(73) Assignee: APPLIED MATERIALS ISRAEL LTD., Rehovot (IL)

(21) Appl. No.: 18/237,854

(22) Filed: Aug. 24, 2023

Related U.S. Application Data
(63) Continuation-in-part of application No. 17/947,481, filed on Sep. 19, 2022.

(51) Int. Cl. H01J 37/26; H01J 37/244; H01J 37/28

(52) U.S. Cl. CPC H01J 37/265; H01J 37/244; H01J 37/28; H01J 2237/24475; H01J 2237/24495; H01J 2237/24507

(57) ABSTRACT

Disclosed herein is a system for non-destructive depth-profiling of samples. The system includes: (i) an electron beam (e-beam) source for projecting e-beams at each of a plurality of landing energies on an inspected sample; (ii) an electron sensor for obtaining a measured set of electron intensities pertaining to each of the landing energies; and (iii) processing circuitry for determining a set of structural parameters, which characterizes an internal geometry and/or a composition of the inspected sample, based on the measured set of electron intensities and taking into account reference data indicative of an intended design of the inspected sample.

### CROSS-REFERENCES TO RELATED APPLICATIONS

This application is a continuation-in-part of U.S. patent application Ser. No. 17/947,481, filed Sep. 19, 2022, the contents of which are hereby incorporated by reference in its entirety.

### TECHNICAL FIELD

The present disclosure relates generally to non-destructive scanning electron microscopy-based depth-profiling of samples.

### BACKGROUND OF THE INVENTION

“Three-dimensional” structures are increasingly used in the semiconductor industry, particularly, in the manufacture of logic and memory components. Accordingly, the ability to obtain structural data of a sample, and to analyze the obtained data to extract a three-dimensional characterization of the sample, has become crucial. At present, most depth-profiling techniques are destructive, typically involving transmission electron microscopy (TEM) and/or the extraction of lamellas, or shaving off of slices, from the sample and subsequent analysis thereof. The challenge remains to develop non-destructive depth-profiling techniques, which will allow for high-volume manufacturing (HVM).

### BRIEF SUMMARY OF THE INVENTION

Aspects of the disclosure, according to some embodiments thereof, relate to non-destructive scanning electron microscopy based depth-profiling of samples. More specifically, but not exclusively, aspects of the disclosure, according to some embodiments thereof, relate to non-destructive depth-profiling of semiconductor structures based on sensing of (at least) backscattered electrons. Even more specifically, but not exclusively, aspects of the disclosure, according to some embodiments thereof, relate to validation of the concentrations of one or more substances in memory and logic components, such as gate stacks, based on sensing of (at least) backscattered electrons.

Thus, according to an aspect of some embodiments, there is provided a computer-based method for non-destructive depth-profiling of samples. The method includes:
A measurement operation including obtaining a measured set of electron intensities by performing, for each of a plurality of landing energies, selected so as to allow probing an inspected sample to a plurality of depths, suboperations of:
   Projecting an electron beam (e-beam) on the inspected sample, which penetrates the inspected sample and induces scattering of electrons from a respective volume thereof determined by the landing energy.
   ▪Measuring an electron intensity by sensing electrons (e.g. backscattered electrons) returned from the inspected sample.
A data analysis operation including determining a set of structural parameters, which characterizes an internal geometry and/or a composition of the inspected sample, based on the measured set of electron intensities and taking into account reference data indicative of an intended design of the inspected sample.

According to some embodiments of the method, the reference data include design data of the inspected sample and/or ground truth (GT) data of other samples of the same intended design as the inspected sample and/or GT data of especially prepared samples exhibiting selected variations with respect to the intended design.

According to some embodiments of the method, the set of structural parameters specifies a concentration map of the inspected sample.

According to some embodiments of the method, the concentration map quantifies a dependence of a concentration of a target substance, which the inspected sample includes, at least on the depth. That is, at each map coordinate(s) the concentration map specifies the density of the target substance. According to some such embodiments, the density is specified to within respective density range from a plurality of density ranges.

According to some embodiments of the method, the set of structural parameters specifies a plurality of concentration maps pertaining to a plurality of target substances included in the inspected specimen.

According to some embodiments of the method, at each map coordinate(s) the concentration map specifies a substance, which has a highest density about the map coordinate(s) out of a plurality of substances, which the inspected sample includes.

According to some embodiments of the method, the density is a mass density, a particle density (e.g., atomic density), or a function of the mass density and the particle density.

According to some embodiments of the method, the set of structural parameters includes one or more of (i) one or more overall concentrations of one or more substances, respectively, that the inspected sample includes, and (ii) at least one width of at least one structure, respectively, which is embedded in the inspected sample, and, additionally, or alternatively, when the inspected sample includes a plurality of layers, (iii) at least one thickness of at least one of the plurality of layers, respectively, (iv) a combined thickness of at least some of the plurality of layers, and (v) at least one mass density of at least one of the plurality of layers, respectively.

According to some embodiments of the method, in the measurement operation, the e-beams are projected so as to impinge on the inspected sample at each of controllably selectable lateral locations thereon, and in the data analysis operation, the set of structural parameters is generated taking into account measured sets of electrons intensities, which are obtained for each of the lateral locations, respectively.

According to some embodiments of the method, (i) in the measurement operation, the e-beams are projected so as to impinge on the inspected sample at each of controllably selectable lateral locations thereon, (ii) the concentration map is three-dimensional, and (iii) in the data analysis operation, the concentration map is generated taking into account measured sets of electrons intensities, which are obtained for each of the lateral locations, respectively.

According to some embodiments of the method, the sensed electrons include backscattered electrons. According to some such embodiments, the sensed electrons further include secondary electrons.

According to some embodiments of the method, the inspected sample is a semiconductor specimen.

According to some embodiments of the method, the sample is a patterned wafer.

According to some embodiments of the method, the sample includes a semiconductor structure.

According to some embodiments of the method, in the data analysis operation, in order to determine the set of structural parameters, a trained algorithm is executed. The trained algorithm is configured to receive as an input the measured set of electron intensities, either raw or following initial processing. Each intensity may be labelled by the landing energy of the respectively inducing e-beam. According to some such embodiments, wherein three-dimensional information of the inspected sample is sought, each intensity is further labelled by lateral coordinates of the lateral location at which the respectively inducing e-beam was projected.

According to some embodiments of the method, the initial processing may include isolating, or at least amplifying, contributions to the raw measured set of electron intensities of the backscattered electrons induced by the projected e-beams.

According to some embodiments of the method, weights of the trained algorithm are determined through training using the reference data and (i) measured sets of electron intensities of other samples of the same intended design as the inspected sample, and/or (ii) simulated sets of electron intensities obtained by simulating impinging of samples of the same intended design as the inspected sample with e-beams at each of a plurality of landing energies.

According to some embodiments of the method, the trained algorithm is or includes a neural network (NN).

According to some embodiments of the method, the trained algorithm is or includes a linear model-incorporating algorithm. That is, the trained algorithm is or includes a linear regression model or incorporates a linear regression model as a sub-algorithm.

According to some embodiments of the method, the NN is selected from a convolutional NN and a fully connected NN.

According to some embodiments of the method, the NN is a regression NN.

According to some embodiments of the method, the NN is a classification NN.

According to some embodiments of the method, the classification NN is a convolutional NN, an AlexNet, a residual NN (ResNet), or a VGG NN, or includes a VAE.

According to some embodiments of the method, wherein at each map coordinate(s) the concentration map specifies a substance, which has a highest density about the map coordinate(s), out of a plurality of substances, which the sample includes, the NN is a classification NN.

According to some embodiments of the method, wherein at each map coordinate(s) the concentration map specifies densities of the one or more substances, which the sample includes, to within a respective density range from a plurality of density ranges, the NN is a classification NN.

According to some embodiments of the method, the measurement operation includes sensing electrons returned each of two or more return angles, respectively.

According to some embodiments of the method, the sensing of the electrons includes, for each of a plurality of pixels on an electron image sensor, measuring a respective intensity of electrons returned thereto (i.e., incident on the pixel).

According to some embodiments of the method, for each landing energy, elastic interactions between electrons from the e-beam and the inspected sample, leading to backscattering of electrons from the e-beam, are substantially limited to a respective volume within the inspected sample, which is substantially centered about a depth that increases with the landing energy and whose size increases with the landing energy.

According to an aspect of some embodiments, there is provided a system for non-destructive depth-profiling of samples. The system includes:
An electron beam (e-beam) source for projecting on an inspected sample e-beams at each of a plurality of landing energies.
An electron sensor (or, more generally, an electron sensing module, which may include a plurality of electron sensors) for obtaining a measured set of electron intensities pertaining to each of the landing energies.
Processing circuitry (also referrable to as “computational module”) for determining a set of structural parameters, which characterizes an internal geometry and/or a composition of the inspected sample, based on the measured set of electron intensities and taking into account reference data indicative of an intended design of the inspected sample.

According to some embodiments of the system, each of the e-beams is configured to penetrate the inspected sample to a respective depth, determined by the respective landing energy, such that the inspected sample is probed over a desired range of depths.

According to some embodiments of the system, the electron sensor is configured to sense electrons returned from the inspected sample (thereby obtaining the measured set of electron intensities).

According to some embodiments of the system, the reference data include design data of the inspected sample and/or ground truth (GT) data of other samples of the same intended design as the inspected sample and/or GT data of especially prepared samples exhibiting selected variations with respect to the intended design.

According to some embodiments of the system, the set of structural parameters specifies a concentration map of the inspected sample.

According to some embodiments of the system, the concentration map quantifies a dependence of a concentration of a target substance, which the inspected sample includes, at least on the depth. That is, at each map coordinate(s) the concentration map specifies the density of the target substance. According to some such embodiments, the density is specified to within respective density range from a plurality of density ranges.

According to some embodiments of the system, the set of structural parameters specifies a plurality of concentration maps pertaining to a plurality of target substances included in the inspected specimen.

According to some embodiments of the system, at each map coordinate(s) the concentration map specifies a substance, which has a highest density about the map coordinate(s) out of a plurality of substances, which the inspected sample includes.

According to some embodiments of the system, the density is a mass density, a particle density (e.g., atomic density), or a function of the mass density and the particle density.

According to some embodiments of the system, the set of structural parameters includes one or more of (i) one or more overall concentrations of one or more substances, respectively, that the inspected sample includes, and (ii) at least one width of at least one structure, respectively, which is embedded in the inspected sample, and, additionally, or alternatively, when the inspected sample includes a plurality of layers, (iii) at least one thickness of at least one of the plurality of layers, respectively, (iv) a combined thickness of at least some of the plurality of layers, and (v) at least one mass density of at least one of the plurality of layers, respectively.

According to some embodiments of the system, the system is further configured to allow projecting the e-beams so as to impinge on the inspected sample at each of controllably selectable lateral locations thereon, and the processing circuitry is configured to, in determining the set of structural parameters, take into account measured sets of electron intensities obtained by the electron sensor for each of the lateral locations.

According to some embodiments of the system, (i) the system is further configured to allow projecting the e-beams so as to impinge on the inspected sample at each of controllably selectable lateral locations thereon, (ii) the concentration map is three-dimensional, and (iii) the processing circuitry is configured to, in generating the concentration map, take into account measured sets of electron intensities obtained by the electron sensor for each of the lateral locations.

According to some embodiments of the system, each intensity in the measured set of electron intensities is labelled by the landing energy of the respectively inducing e-beam.

According to some embodiments of the system, wherein three-dimensional information of the inspected specimen is sought, each of the measured sets of electron intensities is labelled by the lateral location at which the respectively inducing e-beams were projected.

According to some embodiments of the system, the sensed electrons include backscattered electrons. According to some such embodiments, the sensed electrons further include secondary electrons.

According to some embodiments of the system, the electron sensor is a backscattered electron (BSE) detector.

According to some embodiments of the system, the electron sensor is part of an electron sensor array (also referrable to as “electron sensing module”), which the system includes, and which is configured to sense backscattered electrons returned at each of two or more return angles, respectively. According to some such embodiments, the electron sensor array includes a plurality of BSE detectors.

According to some embodiments of the system, the inspected sample is a semiconductor specimen.

According to some embodiments of the system, the inspected sample is a patterned wafer.

According to some embodiments of the system, the inspected sample includes a semiconductor structure.

According to some embodiments of the system, in order to determine the set of structural parameters, the processing circuitry is configured to execute a trained algorithm (an algorithm derived using machine-learning (ML) tools, also referred to as “ML-derived algorithm”). The trained algorithm is configured to receive as an input the measured set of electron intensities either raw or following initial processing by the processing circuitry. Each intensity may be labelled by the landing energy of the respectively inducing e-beam. According to some such embodiments, wherein three-dimensional information of the inspected sample is sought, each intensity is further labelled by lateral coordinates of the lateral location at which the respectively inducing e-beam was projected.

According to some embodiments of the system, the initial processing may include isolating, or at least amplifying, contributions to the raw measured set of electron intensities of the backscattered electrons induced by the projected e-beams.

According to some embodiments of the system, weights of the trained algorithm are determined through training using the reference data and (i) measured sets of electron intensities of other samples of the same intended design as the inspected sample, and/or (ii) simulated sets of electron intensities obtained by simulating impinging of samples of the same intended design as the inspected sample with e-beams at each of a plurality of landing energies.

According to some embodiments of the system, the trained algorithm is or includes a neural network (NN).

According to some embodiments of the system, the trained algorithm is or includes a linear model-incorporating algorithm. That is, the trained algorithm is or includes a linear regression model or incorporates a linear regression model as a sub-algorithm.

According to some embodiments of the system, the NN is selected from a convolutional NN and a fully connected NN.

According to some embodiments of the system, the NN is a regression NN.

According to some embodiments of the system, the NN is a classification NN.

According to some embodiments of the system, the classification NN is a convolutional NN, an AlexNet, a residual NN (ResNet), or a VGG NN, or includes a VAE.

According to some embodiments of the system, wherein at each map coordinate(s) the concentration map specifies a substance, which has a highest density about the map coordinate(s), out of a plurality of substances, which the sample includes, the NN is a classification NN.

According to some embodiments of the system, wherein at each map coordinate(s) the concentration map specifies densities of the one or more substances, which the sample includes, to within a respective density range from a plurality of density ranges, the NN is a classification NN.

According to some embodiments of the system, the electron sensor is an electron image sensor.

According to some embodiments of the system, for each landing energy, elastic interactions between electrons from the e-beam and the inspected sample, leading to backscattering of electrons from the e-beam, are substantially limited to a respective volume within the inspected sample, which is substantially centered about a depth that increases with the landing energy and whose size increases with the landing energy.

According to some embodiments of the system, the e-beam source and the electron sensor form part of a scanning electron microscope (SEM).

According to an aspect of some embodiments, there is provided a method for training a neural network (NN) for non-destructive depth-profiling of samples. The method includes operations of:
Generating simulated training data for a NN, which is configured to (i) receive as an input, a set of electron intensities pertaining to a sample, obtained by projecting on the sample electron beams (e-beams) at each of a plurality of landing energies, and (ii) output a set of structural parameters characterizing an internal geometry and/or a composition of the sample, by sub-operations of:
   For each of a plurality of ground truth (GT) samples, generating calibration data, by:
      Obtaining a measured set of electron intensities by projecting on the GT sample a plurality of e-beams at a first plurality of landing energies, respectively, and sensing electrons (e.g. backscattered electrons) returned from the sample.
      Obtaining GT data characterizing the GT sample.
   Using the calibration data to calibrate a computer simulation, which is configured to receive as inputs GT data characterizing a sample and landing energies of e-beams, and output a corresponding simulated set of electron intensities.
   Using the calibrated computer simulation to generate additional simulated set of electron intensities corresponding to other samples (i.e. other GTs) and/or additional landing energies.
Training the NN using at least the simulated training data.

According to some embodiments of the training method, the measured GT data specify concentration maps of one or more substances, which each of the GT samples nominally includes.

According to some embodiments of the training method, the set of structural parameters specifies a concentration map of a target substance from the one or more substances.

According to some embodiments of the training method, the computer simulation is calibrated such that for each pair of (i) measured GT data obtained in the suboperation of generating the calibration data, and (ii) a landing energy utilized in the suboperation of generating the calibration data, which is input into the computer simulation, a simulated intensity, which is output by the computer simulation, agrees to within a required precision with the measured intensity.

According to some embodiments of the training method, the sensed electrons include backscattered electrons. According to some such embodiments, the sensed electrons further include secondary electrons.

According to some embodiments of the training method, prior to the calibration suboperation, the computer simulation specifies initial point spread functions (PSFs) at least for each of the first plurality of landing energies. In the calibration suboperation, the initial PSFs are calibrated, thereby obtaining calibrated PSFs.

According to some embodiments of the training method, as part of the calibration thereof, each of the initial PSFs is piecewise linearized as a function of a density of a target substance, which the GT samples nominally include.

According to some embodiments of the training method, the calibrated PSFs are obtained by about maximizing a likelihood for obtaining the sensed electrons data sets, given the measured GT data and starting from the initial PSFs. According to some such embodiments, as part of the maximization, regularization is used.

According to some embodiments of the training method, a modified Richardson-Lucy algorithm is applied to obtain the calibrated PSFs from the initial PSFs.

According to some embodiments of the training method, an adjustable U-Net deep learning NN is used to obtain the calibrated PSFs from the initial PSFs. Parameters of the U-Net deep learning NN are optimized over under the constraint that the measured sets of electron intensities are obtained from the measured GT data, respectively, when the respective calibrated PSFs, obtained from the initial PSFs using the U-Net deep learning NN, are used.

According to some embodiments of the training method, the other samples are of different intended design(s) than the plurality of GT samples.

According to some embodiments of the training method, the method may further include reapplying (i.e., performing again) the suboperation of generating the simulated training data and the operation of training the NN when additional calibration data is available.

According to some embodiments of the training method, a ratio of a number of the simulated sets of electron intensities to a number of the measured sets of electron intensities may be between about 100 and about 1,000.

According to some embodiments of the training method, the GT data are obtained by profiling lamellas extracted from each of the plurality samples and/or slices shaved thereof.

According to some embodiments of the training method, the profiling of lamellas and/or the slices is performed using transmission electron microscopy and/or a scanning electron microscopy.

According to some embodiments of the training method, each of the plurality of GT samples is or includes a semiconductor specimen.

According to some embodiments of the training method, each of the plurality of GT samples is a patterned wafer.

According to some embodiments of the training method, each of the plurality of GT samples includes a semiconductor structure.

According to some embodiments of the training method, the NN is a classification NN. The concentration map (output by the NN) specifies at each map coordinate(s) a substance, which, out of a plurality of substances included in an inspected sample, has the highest density about the map coordinate(s).

According to some embodiments of the training method, the NN is a classification NN. The concentration map (output by the NN) specifies to within one of a plurality of density ranges at each map coordinate(s) a density of a target substance, which an inspected sample includes. According to some such embodiments, the NN is configured to output a plurality of concentration maps pertaining to a plurality of target substances, which the inspected sample includes.

According to some embodiments of the training method, the classification NN is a convolutional NN, an AlexNet, a residual NN (ResNet), or a VGG NN, or includes a VAE.

According to some embodiments of the training method, the density is a mass density, a particle density (e.g., atomic density), or a function of the mass density and the particle density.

According to some embodiments of the training method, the NN is a regression NN selected from a convolutional NN and a fully connected NN.

According to some embodiments of the training method, the suboperation of generating the calibration data includes sensing electrons returned at two or more scattering angles.

According to some embodiments of the training method, the NN is configured to (i) receive as inputs measured sets of electron intensities obtained for each of a plurality of lateral locations on an inspected sample at which the inducing e-beams respectively impinge, and (ii) output a three-dimensional concentration map of the inspected sample. Each of the measured sets of electron intensities is labelled by the lateral location on which the respectively inducing e-beam impinged on the inspected sample. In the generating of the calibration data, the pluralities of e-beams are projected at pluralities of lateral locations on each of the GT samples.

According to an aspect of some embodiments, there is provided a non-transitory computer-readable storage medium storing instructions that cause a system for non-destructive depth-profiling of samples (such as the above-described system) to implement the above-described method for non-destructive depth-profiling of samples.

Certain embodiments of the present disclosure may include some, all, or none of the above advantages. One or more other technical advantages may be readily apparent to those skilled in the art from the figures, descriptions, and claims included herein. Moreover, while specific advantages have been enumerated above, various embodiments may include all, some, or none of the enumerated advantages.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more” unless the context clearly dictates otherwise.

Unless specifically stated otherwise, as apparent from the disclosure, it is appreciated that, according to some embodiments, terms such as “processing”, “computing”, “calculating”, “determining”, “estimating”, “assessing”, “gauging” or the like, may refer to the action and/or processes of a computer or computing system, or similar electronic computing device, that manipulate and/or transform data, represented as physical (e.g. electronic) quantities within the computing system's registers and/or memories, into other data similarly represented as physical quantities within the computing system's memories, registers or other such information storage, transmission or display devices.

Embodiments of the present disclosure may include apparatuses for performing the operations herein. The apparatuses may be specially constructed for the desired purposes or may include a general-purpose computer(s) selectively activated or reconfigured by a computer program stored in the computer. Such a computer program may be stored in a computer readable storage medium, such as, but not limited to, any type of disk including floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), magnetic or optical cards, flash memories, solid state drives (SSDs), or any other type of media suitable for storing electronic instructions, and capable of being coupled to a computer system bus.

The processes and displays presented herein are not inherently related to any particular computer or other apparatus. Various general-purpose systems may be used with programs in accordance with the teachings herein, or it may prove convenient to construct a more specialized apparatus to perform the desired method(s). The desired structure(s) for a variety of these systems appear from the description below. In addition, embodiments of the present disclosure are not described with reference to any particular programming language. It will be appreciated that a variety of programming languages may be used to implement the teachings of the present disclosure as described herein.

Aspects of the disclosure may be described in the general context of computer-executable instructions, such as program modules, being executed by a computer. Generally, program modules include routines, programs, objects, components, data structures, and so forth, which perform particular tasks or implement particular abstract data types. Disclosed embodiments may also be practiced in distributed computing environments where tasks are performed by remote processing devices that are linked through a communications network. In a distributed computing environment, program modules may be located in both local and remote computer storage media including memory storage devices.

### BRIEF DESCRIPTION OF THE DRAWINGS

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not drawn to scale. Moreover, two different objects in the same figure may be drawn to different scales. In particular, the scale of some objects may be greatly exaggerated as compared to other objects in the same figure.

In the figures:

FIG. 1 presents a flowchart of a non-destructive scanning electron microscopy-based method for depth-profiling of samples, according to some embodiments;

FIG. 2A to 2D schematically depict a sample undergoing depth-profiling in accordance with the method of FIG. 1, according to some embodiments;

FIG. 3 presents a flowchart of a non-destructive scanning electron microscopy-based method for depth-profiling of samples, which corresponds to specific embodiments of the method of FIG. 1, wherein the depth-profiling is three-dimensional;

FIGS. 4A and 4B schematically depict a sample undergoing depth-profiling in accordance with the method of FIG. 3, according to some embodiments thereof;

FIG. 5 schematically depicts a sample undergoing depth-profiling in accordance with the method of FIG. 3, according to some embodiments thereof;

FIG. 6 schematically depicts a system for non-destructive scanning electron microscopy-based depth-profiling of samples, according to some embodiments;

FIG. 7 schematically depicts an electron irradiation and sensing assembly, which corresponds to specific embodiments of an electron irradiation and sensing assembly of the system of FIG. 6; and

FIG. 8 presents a method for training a neural network to derive from backscattered electrons data, obtained from a sample, a concentration map thereof, according to some embodiments.

### DETAILED DESCRIPTION OF THE INVENTION

The principles, uses, and implementations of the teachings herein may be better understood with reference to the accompanying description and figures. Upon perusal of the description and figures present herein, one skilled in the art will be able to implement the teachings herein without undue effort or experimentation. In the figures, same reference numerals refer to same parts throughout.

As used herein, the acronyms “SEM” and “BSE” stand for “scanning electron microscope” and “backscattered electrons”, respectively. “E-beam” stands for “electron beam”.

The present application, according to some embodiments thereof, is directed at methods and systems for non-destructive depth-profiling of samples based on BSE measurements: E-beams at each of a plurality of landing energies are projected on a sample. Each e-beam penetrates into the sample and induces backscattering of electrons from a respective volume (also referred to as “probed region”) within the sample. The greater the landing energy, the greater the depth about which the probed region is centered.

The present application teaches how BSE measurement data from multiple probed regions, which are centered about multiple depths, respectively, may be jointly processed to determine a set of structural parameters of a sample. In particular, the present application teaches how BSE measurement data from multiple probed regions, which are centered about multiple depths, respectively, may be jointly processed to generate a high-resolution concentration map(s) of a sample. According to some embodiments, the processing involves utilizing a trained algorithm, such as a (trained) neural network or a (trained) linear model-incorporating algorithm (defined below). Advantageously, the present application further discloses methods whereby a neural network may be trained to perform such processing starting out from a small set of ground truth data. More precisely, the present application teaches how to amplify a small training set of (measured) ground truth data and associated actual BSE measurement data to obtain an arbitrarily larger training set of simulated “ground truth” data and associated simulated BSE measurement data, which may be used to train the algorithm.

### Depth-Profiling Methods

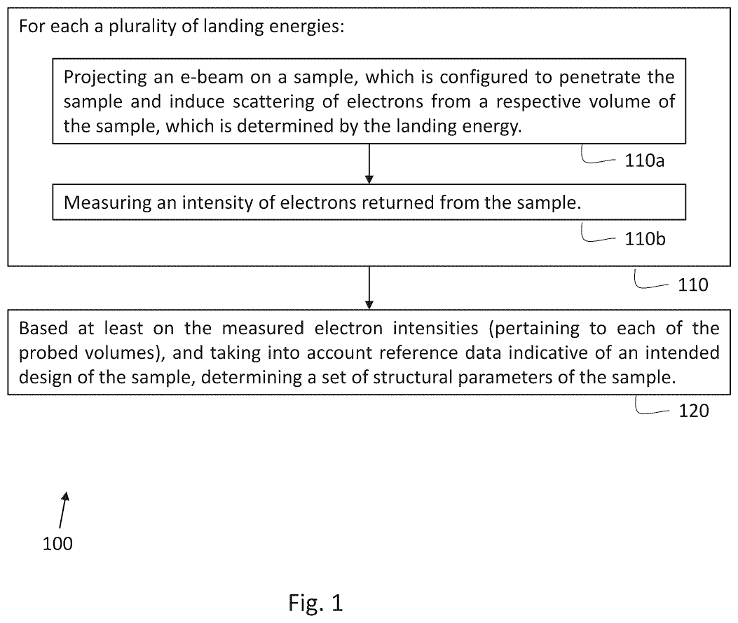

According to an aspect of some embodiments, there is provided a computerized method for non-destructive depth-profiling of samples (e.g. semiconductor structures) based on scanning electron microscopy. FIG. 1 presents a flowchart of such a method, a method 100, according to some embodiments. Method 100 includes:
A measurement operation 110, which includes obtaining a measured set of electron intensities (i.e. a plurality of measured intensities of electrons). The measured set of electron intensities is obtained by performing, for each of a plurality of landing energies of electron beams (e-beams)—selected so as to probe a sample, which is being inspected (also referred to as “the inspected sample”), to a plurality of depths—suboperations of:
   A suboperation 110a, wherein an e-beam is projected on the inspected sample. The e-beam penetrates the inspected sample and induces backscattering of electrons from a respective volume (also referred to as “probed region”) of the inspected sample at a respective depth, which is determined by the landing energy.
   ▪A suboperation 110b, wherein an intensity of scattered electrons (e.g. backscattered electrons) returned from the inspected sample is measured.
A data analysis operation 120, wherein a set of structural parameters of the inspected sample is determined based on the measured set of electron intensities (i.e. the totality of measurement data obtained by sensing the scattered electrons in each of the implementations of suboperation 110b) and taking into account reference data indicative of an intended design of the inspected sample. The set of structural parameters characterizes an internal geometry and/or a (material) composition of the inspected sample.

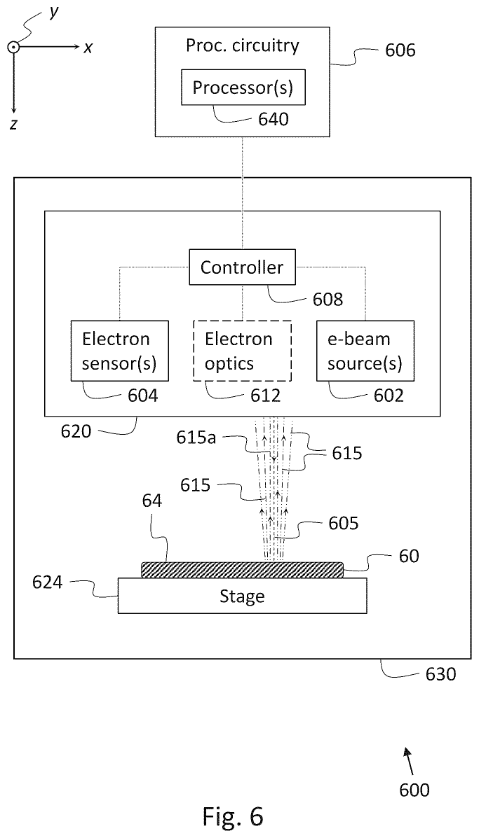

Method 100 may be implemented using a system, such as the system described below in the description of FIG. 6, or a system similar thereto.

According to some embodiments, and as described in detail below, data analysis operation 120 may involve utilizing an algorithm, which is configured to: (i) receive as an input (at least) the measured set of electron intensities (optionally, after processing, as detailed below) and (ii) output the set of structural parameters. According to some embodiments, the algorithm is trained using training data, which include, or are derived from, the reference data. As used herein, the term “reference data” may refer to structural information, which is initially available (i.e. prior to implementing method 100) and which specifies, or is indicative of, a nominal internal geometry and/or a nominal composition of an inspected sample. The structural information may include (i) design data of the inspected sample and/or (ii) ground truth (GT) data indicative of the intended design of the inspected sample. Such GT data may be obtained by profiling, potentially destructively (e.g., using scanning electron microscopy or transmission electron microscopy), other samples (also referred to as “GT samples”) of the same intended design as the inspected sample. According to some embodiments, the GT data may specify density distributions of one or more substances (compounds and/or elements) nominally included in the GT samples. It is noted that GT data will typically slightly differ from design data in additionally reflecting production imperfections. According to some embodiments, the structural information may include “simulated” GT data, particularly, structural information pertaining to “simulated” samples of the same intended design as the inspected sample but which slightly differ from one another, e.g. as would be expected due to manufacturing imperfections.

According to some embodiments, GT samples may be especially prepared so as to reflect the range of variation of a structural parameter from a selected minimum value of the structural parameter to a selected maximum value thereof.

More specifically, according to some embodiments, the training data may include the reference data and associated actual (i.e., measured) sets of electron intensities (optionally, after initial processing of the electron intensities) and/or simulated sets of electron intensities. The actual sets of electron intensities may be derived by implementing measurement operation 110 with respect to other samples (i.e., GT samples) of the same intended design as the inspected sample and/or especially prepared samples exhibiting a selected variation(s) with respect to the intended design (i.e., the nominal design). The simulated sets of electron intensities may be derived by simulating application of measurement operation 110 with respect to “simulated” samples of the same intended design as the inspected sample but which slightly differ from one another (e.g., as would be expected due to manufacturing imperfections). It is noted that in embodiments wherein, in data analysis operation 120, the measurement data (i.e., the measured set of electron intensities) are subject to initial processing prior to being input into the algorithm, the simulated set of electron intensities is configured to simulate the obtained measurement data following the initial processing thereof. Initial processing of the measured set of electron intensities may be employed in order to account for noise and, more generally, amplify the contribution of backscattered electrons to the measured set of electron intensities.

As used herein, the term “structural parameter” is to be understood in a broad manner and encompasses both geometrical parameters, such as the thickness of a layer of a layered sample, and compositional parameters, such as an (overall) concentration of a substance included in a sample. In particular, according to some embodiments, the term “set of structural parameters” may be used to refer to a set of parameters and/or a function specifying at least one density distribution (mass distribution or particle distribution) of at least one target substance, respectively, which is included in an inspected sample. As used herein, according to some embodiments, the term “set” may refer to a plurality of elements, while according to some other embodiments, the term “set” may refer to a single element. A specific instance of the former case is when the set is constituted by a function. According to some embodiments, each element of a set may represent a datum (e.g. a value of a parameter) or data (e.g. values of a plurality of parameters).

As used herein, according to some embodiments, the term “target substance” refers to a substance included in an inspected sample and whose density distribution is to be determined using method 100.

According to some embodiments, the inspected sample is a patterned wafer, a part of a patterned wafer, or a semiconductor device included in (e.g., embedded in or on) a patterned wafer, optionally, in one of the fabrication stages of the patterned wafer. According to some embodiments, the inspected sample is or includes a structure including one or more semiconductor materials. According to some embodiments, the structure may be constructed as part of the manufacturing process of a semiconductor device and/or a component(s) of a semiconductor device. According to some embodiments, the structure may be an assist structure, which is constructed as part of the manufacturing process of a semiconductor device and/or a component(s) of a semiconductor device. According to some embodiments, the inspected sample may be or include one or more logic components (e.g., a fin FET (FinFET) and/or a gate-all-around (GAA) FET) and/or memory components (e.g., a dynamic RAM and/or a vertical NAND (V-NAND)), optionally, in one of the fabrication stages thereof. According to some embodiments, the inspected sample is layered (i.e., including a plurality of layers). According to some such embodiments, the set of structural parameters includes a plurality of parameters characterizing each of at least some of the plurality of layers.

According to some embodiments, the set of structural parameters specifies a concentration map(s) of the inspected sample. According to some embodiments, the concentration map is a density distribution quantifying the dependence at least on the depth of (i) the mass density or relative mass density (i.e., percentage by weight per unit volume) of a target substance or (ii) the particle density (e.g., atomic density) or relative particle density (e.g., atomic percent per unit volume) of the target substance. As used herein, the term “particles”, when employed in relation to a substance, refers to one or more types of atoms, and/or one or more types of molecules, of which the substance is composed. The term “relative particle density”, when employed in relation to a first substance, refers to the ratio of the number particles—making up the first substance—per unit volume to the total number of particles (i.e., of all substances included in the inspected sample) per unit volume. According to some alternative embodiments, the concentration map characterizes the depth-dependence (or at least the depth-dependence) of a function of both the mass density and the particle density.

According to some embodiments, the set of structural parameters specifies a plurality of density distributions of a plurality of target substances, respectively, included in the inspected sample.

According to some embodiments, wherein the set of structural parameters specifies a concentration map, at each map coordinate(s) the concentration map specifies the substance that has the highest density out of all substances, or a predefined set of substances, present (i.e., found) about the map coordinate(s). More precisely, in the one-dimensional case, for each vertical map coordinate, or equivalently, for each thin lateral layer of the inspected sample, the concentration map may specify the substance having the highest density. In the three-dimensional case, for each triplet of map coordinates (e.g., the vertical coordinate and two lateral (i.e., horizontal) coordinates), or equivalently, for each voxel of the inspected sample, the concentration map may specify the substance having the highest density. Thus, each thin layer in the one-dimensional case, and each voxel in the three-dimensional case, may be classified according to the substance exhibiting the highest concentration (e.g., particle density).

According to some embodiments, wherein the set of structural parameters specifies a concentration map, at each map coordinate(s) (i.e., a single coordinate specifying the depth in the one-dimensional case and three coordinates in the three-dimensional case) the concentration map specifies the density of a target substance (which the sample includes) to within a respective density range from a plurality of density ranges. That is, the density may be specified by a non-negative integer, such that for any given specific value i of the (non-negative) integer the density is determined to a range [i·Δξ, (i+1)·Δξ]. Here Δξ is the magnitude of (each of) the ranges (i.e., the particle or mass density resolution, as provided by the specific embodiment of method 100 which is employed). Alternatively, according to some embodiments, at each map coordinate(s) the density of the target substance may be specified in terms of a numerical value from a continuous range of numerical values.

It is noted that method 100 may be used to validate the density distributions of one or more substances within an inspected sample. More specifically, method 100 may be used to quantify small variations (e.g., to within 1%, 3%, or even 5%) from a nominal density distribution (specified by the design intent) of a target substance in an inspected sample. According to some embodiments, at each map coordinate(s), the concentration map may specify the difference in the density of the target substance relative to the nominal density thereof (which may be specified in terms of mass density, relative mass density, particle density, or relative particle density). According to some such embodiments, at each map coordinate(s) the difference may be specified to within a respective difference interval from a plurality of difference intervals (density ranges). According to some embodiments, at each map coordinate(s), the concentration map may specify the actual density of the target substance (which may be specified in terms of mass density, relative mass density, particle density, or relative particle density)—i.e., the density computed in data analysis operation 120. According to some such embodiments, at each map coordinate(s) the actual density may be specified to within a respective density range from a plurality of density ranges.

According to some embodiments, wherein (i) the set of structural parameters specifies two concentration maps of two different substances (e.g. a light element and a heavy element), respectively, which are included in the inspected sample, and (ii) the densities are specified in terms of mass, the density resolutions of the two substances may differ: The mass density of the first substance may be specified to a first mass density resolution Δξ₁ and the mass density of the second substance may be specified to a second mass density resolution Δξ₂, wherein Δξ₂≠Δξ₁ (reflecting the difference in BSE yields, or equivalently the BSE coefficients, between the two substances).

Additionally, or alternatively, according to some embodiments, the set of structural parameters may include one or more of: (i) at least one average density (i.e., overall mass concentration and/or overall particle concentration) of at least one substance, respectively, that the inspected sample includes, and (ii) at least one width of at least one target structure, respectively, which is embedded in the inspected sample. In embodiments wherein the inspected sample is layered (i.e. including a plurality of layers), the set of structural parameters may include or additionally include: (iii) at least one thickness of at least one of the layers, respectively, (iv) a combined thickness of at least some of the layers, (v) at least one average density (mass and/or particle) of at least one of the layers, respectively, and (vi) at least one average density (mass and/or particle), in at least one of the layers, of at least one substance (i.e. material), respectively, that the inspected sample includes. More generally, the set of structural parameters may include any geometrical parameter and/or compositional parameter of the inspected sample, whose modification impacts the measured set of electron intensities (obtained in the implementations of suboperation 110b), so as to allow determining the value of the parameter based on the measured set of electron intensities.

It is noted that the task of determining the overall concentration of a target substance (included in an inspected sample) may be less cumbersome than determining the density distribution of the target substance. This applies both to measurement operation 110, wherein, according to some embodiments, comparatively fewer landing energies may be required (i.e., fewer implementations of suboperations 110a and 110b), and to data analysis operation 120, wherein, according to some embodiments, the involved data processing may be comparatively less cumbersome.

According to some embodiments, each of the structural parameters, or at least some of the structural parameters, may be specified to a respective range (of values) from a respective plurality of non-overlapping ranges, which may be complementary. For example, in embodiments wherein the set of structural parameters includes the thickness of a layer, in data analysis operation 120, the thickness may be determined by an integer (which according to some embodiments may be negative), such that for any given specific value i of the integer, the thickness is determined to a range [t+i·Δt, t+(i+1)·Δt]. Here Δt is the magnitude of (each of) the ranges (i.e., the thickness resolution, as provided by the specific embodiment of method 100 which is employed).

According to some embodiments, each of the structural parameters, or at least some of the structural parameters, may be specified in terms of a respective numerical value from a respective continuous range of numerical values.

In each of the implementations of suboperation 110a, parameters of the respectively projected e-beam, particularly the landing energy thereof, are selected so as to induce backscattering of electrons in the e-beam from matter in a volume (probed region) centered about a respective depth within the inspected sample. The number of landing energies, and the minimum and maximum landing energies, may be selected to ensure that the inspected sample is probed over a range of depths. According to some such embodiments, the number of landing energies, and the minimum and maximum landing energies, may be selected to ensure that the inspected sample is probed all along the depth-dimension of the inspected sample.

Suboperation 110b may be implemented using an electron sensor (such as the electron sensor of FIG. 6). According to some embodiments, the electron sensor may be configured to measure the intensity of electrons (e.g., backscattered electrons) incident thereon. According to some embodiments, the electron sensor may be an electron image sensor (e.g., a BSE image detector). That is, the electron sensor may be configured to obtain a two-dimensional image (which specifies the intensities of electrons incident on each pixel, respectively, on the electron sensor). In such embodiments, the measured set of electron intensities includes at least the intensities measured by each pixel on the electron sensor in each of the implementations of suboperation 110b. According to some embodiments, suboperation 110b may be implemented using two or more electron sensors. For example, a first electron sensor (e.g., a first BSE detector) may be positioned so as to collect backscattered electrons returned at a scattering angle of about 180°, while a second electron sensor (e.g. a second BSE detector) may be positioned so as to collect backscattered electrons returned at a scattering angle of about 170°, about 160°, or about 150°. Each possibility corresponds to separate embodiments. In such embodiments, the measured set of electron intensities includes at least the intensities measured by each of the electron sensors in each of the implementations of suboperation 110b.

According to some embodiments, in suboperation 110b, in addition to backscattered electrons, secondary electrons (returned from the inspected sample) are also sensed, thereby obtaining additional measurement data pertaining to secondary electrons. In such embodiments, in data analysis operation 120, the additional measurement data are also taken into account in determining the set of structural parameters.

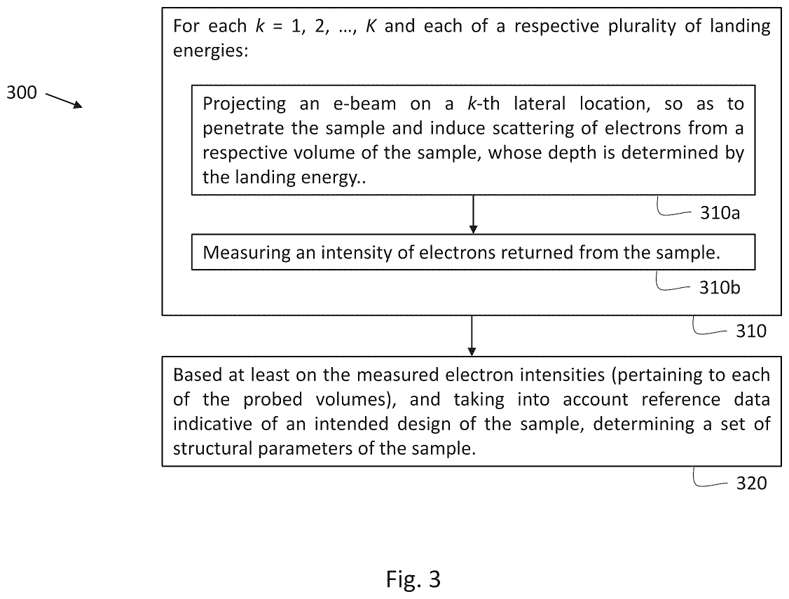

Method 100 may be used to provide a one-dimensional concentration map of an inspected sample or a three-dimensional concentration map of an inspected sample (or a two-dimensional concentration map of an inspected sample). Each possibility corresponds to separate embodiments. In the latter case (i.e., in embodiments wherein method 100 is used for three-dimensional profiling of an inspected sample), and as described in detail below in the description of FIGS. 3-5, measurement operation 110 may be serially implemented with respect to each of a plurality of lateral locations on the inspected sample (e.g., on the top surface of the inspected sample) at which the respective e-beams impinge. The skilled person will readily perceive that by serially implementing measurement operation 110 with respect to each of a plurality of lateral locations on an inspected sample, at which the respective e-beams impinge, lateral variations in the average concentration (the (local) density averaged over the depth dimension) of a target substance may be detected. By “lateral variations” what is meant is variations in parallel to the xy-plane assuming the z-coordinate quantifies the depth. Accordingly, method 100 may be used to obtain a two-dimensional map of the average concentration (averaged over the depth dimension) of a target substance that the inspected sample includes.

More generally, by serially implementing measurement operation 110 with respect to each of a plurality of lateral locations on an inspected sample, and applying data analysis operation 120, variations in values of structural parameters (beyond the local concentrations of one or more target substances or the average concentrations, averaged over the depth dimension, of one or more target substances) may be detected. For example, when the inspected sample is layered, lateral variations (e.g. due to process variation) in the thicknesses of layers may be detected. Accordingly, the lateral variation in the thickness of a layer may be presented in terms of a two-dimensional thickness map specifying the thickness as a function of the lateral (i.e., horizontal) coordinates.

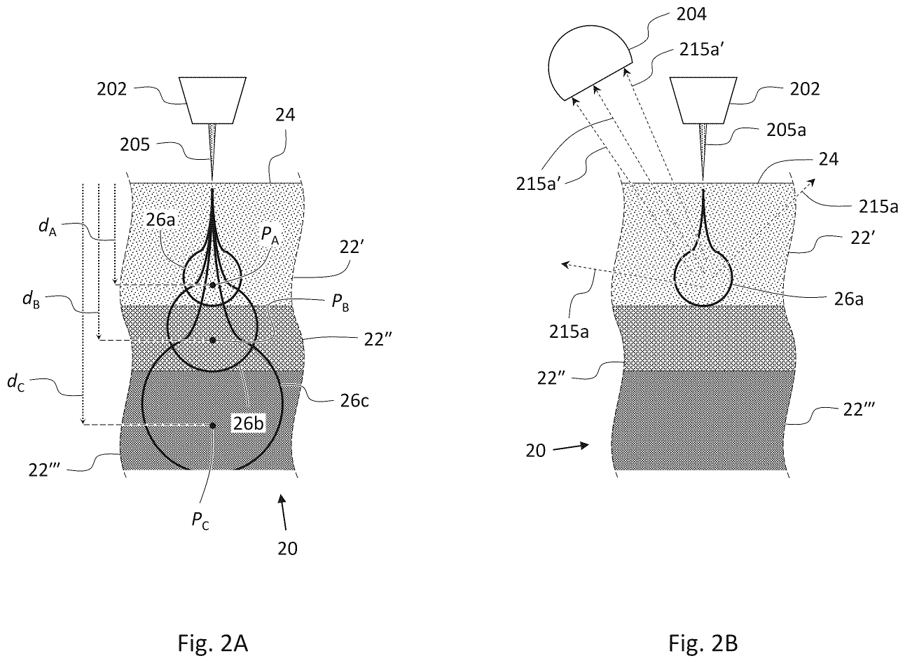

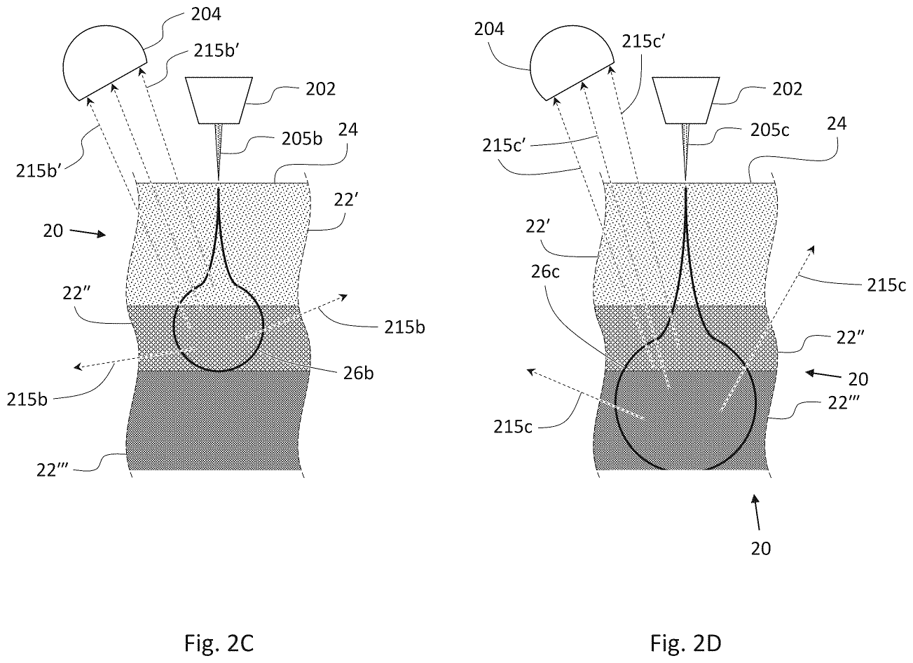

First, the one-dimensional case (i.e. pure depth-profiling without lateral characterization) is described in detail. To this end, reference is additionally made to FIGS. 2A-2D. FIGS. 2A-2D schematically depict an implementation of measurement operation 110 of method 100, according to some embodiments thereof, wherein one-dimensional information of an inspected sample is sought. To facilitate the description by rendering it more concrete, it is assumed that method 100 is employed to generate a one-dimensional concentration map of a target substance included in an inspected sample (e.g., a semiconductor specimen). However, the skilled person will readily grasp the generalization to other tasks, such as the tasks mentioned above (e.g., determination of thicknesses of layers in a layered sample, the determination of average concentrations, averaged over the depth dimension, of one or more target substances, or the determination of the lateral dimensions of a target structure embedded in the inspected sample).

FIG. 2A shows a cross-sectional view of a sample 20 being probed by an e-beam in accordance with measurement operation 110. As a non-limiting illustrative example, it is assumed that sample 20 includes a plurality of lateral (i.e., horizontal) layers 22 with at least some of layers 22 differing from one another in composition (i.e. differing in constituents or, when including the same constituents, differing in the concentrations of the constituents). According to some embodiments, at least some of layers 22 may differ from one another in thickness.

As a non-limiting example, in FIGS. 2A-2D sample 20 is shown as including three layers disposed one on top of the other: a first layer 22′ (from layers 22), a second layer 22″ (from layers 22), and a third layer 22′″ (from layers 22). First layer 22′ is disposed above second layer 22″. Second layer 22″ is sandwiched between first layer 22′ and third layer 22′″. The top surface of first layer 22′ constitutes an external surface 24 of sample 20. Also shown is an e-beam source 202 and an e-beam 205 produced thereby, so as to impinge (e.g., normally impinge) on external surface 24. E-beam source 202 may be configured to project e-beams (one at a time) at each of a plurality of landing energies, thereby implementing suboperation 110a.

The greater the landing energy of e-beam 205, the greater the depth to which electrons from e-beam 205 will (on average) penetrate into sample 20. Further, the greater the landing energy of e-beam 205, the greater may be the probed region, that is, the volume within sample 20 wherein electrons from e-beam 205 elastically interact with matter in sample 20 so as to be scattered. This is exemplified in FIG. 2A via three probed regions 26: A first probed region 26a corresponds to the volume of sample 20 in which occur about all (e.g. at least 80%, at least 90%, or at least 95%) of the elastic interactions that lead to the backscattering of electrons in a penetrating e-beam having a first landing energy E₁. A second probed region 26b corresponds to the volume of sample 20 in which occur about all of the elastic interactions that lead to the backscattering of electrons in a penetrating e-beam having a second landing energy E₂. A third probed region 26c corresponds to the volume of sample 20 in which occur about all of the elastic interactions that lead to the backscattering of electrons in a penetrating e-beam having a third landing energy E₃. First probed region 26a is centered about a first point P_{A} at a depth d_{A}, second probed region 26b is centered about a second point P_{B} at a depth d_{B}, and third probed region 26c is centered about a third point P_{C} at a depth d_{C}. E₁<E₂<E₃. Accordingly, d_{A}<d_{B}<d_{C}. According to some embodiments, and as depicted in FIG. 2A, third probed region 26c is of a greater size than second probed region 26b, which is of a greater size than first probed region 26a.

According to some embodiments, particularly embodiments wherein in data analysis operation 120 a NN is utilized to obtain the concentration map, the required depth resolution of the concentration map dictates the number of landing energies. In particular, the greater the required depth resolution, the greater the number of landing energies utilized. (The minimum and maximum depths, to which an inspected sample is probed, are determined by the smallest and greatest landing energies, respectively.) Accordingly, in such embodiments, the distances between centers of successive probed regions (e.g., the distance d_{B}−d_{A} between P_{A} and P_{B}, the distance d_{C}−d_{B} between P_{B} and P_{C}), are dictated by the required resolution of the concentration map. According to some embodiments, the depth resolution is selected to be sufficiently high to detect and “pin-point” changes in the concentration of the target substance. For example, in the depth-profiling of sample 20, the depth resolution may be selected to be greater than the thickness of the thinnest of layers 22. It is noted that the same may apply also to other structural parameters. For example, according to some embodiments, the accuracy, to which the thicknesses of layers of a layered sample are to be determined, may dictate the number of landing energies.

Alternatively, according to some embodiments, wherein a linear model-incorporating algorithm may be employed in data analysis operation 120 to obtain the concentration map (and, more generally, the set of structural parameters), the number of landing energies employed may be comparatively much smaller. That is, the inspected sample may be probed to each of a small set of preselected and/or random depths (e.g., to capture process variation). As used herein, the term “linear model-incorporating algorithm” may refer to a linear regression model or, more generally, an algorithm incorporating two or more sub-algorithms with one of the sub-algorithms being constituted by a linear regression model.

FIG. 2B shows a first e-beam 205a—generated by e-beam source 202 and having the first landing energy E₁—incident on sample 20. Also delineated is first probed region 26a (from which about all of the sensed backscattered electrons are returned). Arrows 215a indicate backscattered electrons. Arrows 215a′ indicate a fraction (i.e., portion) of the backscattered electrons, which arrive at electron sensor 204.

FIG. 2C shows a second e-beam 205b—generated by e-beam source 202 and having the second landing energy E₂—incident on sample 20. Also delineated is second probed region 26b (from which about all of the sensed backscattered electrons are returned). Arrows 215b indicate backscattered electrons. Arrows 215b′ indicate a fraction of the backscattered electrons, which arrive at electron sensor 204.

FIG. 2D shows a third e-beam 205c—generated by e-beam source 202 and having the third landing energy E₃—incident on sample 20. Also delineated is third probed region 26c (from which about all of the sensed backscattered electrons are returned). Arrows 215c indicate backscattered electrons. Arrows 215c′ indicate a fraction of the backscattered electrons, which arrive at electron sensor 204.

According to some embodiments, electron sensor 204 is a BSE detector. According to some embodiments, not depicted in FIGS. 2B-2D, in addition, to electron sensor 204, one or more additional electron sensors may be used to sense the returned electrons.

For each landing energy (e.g., landing energies E₁, E₂, and E₃), a respective intensity of electrons (e.g., backscattered electrons), which are returned from sample 20 onto electron sensor 204, is measured by electron sensor 204, thereby implementing suboperation 110b. The intensity of backscattered electrons returned from a probed region is indicative of the (material) composition of the probed region. By sensing backscattered electrons induced by each of a sufficiently large plurality of e-beams at a plurality of (different) landing energies, respectively, and subjecting the thus-obtained sensed electrons data sets to a joint analysis (for example, using a trained algorithm as described below), a dependence of the composition on the depth may be extracted (in data analysis operation 120). More specifically, since the presence and spatial distribution of each substance generally gives rise to a unique contribution to the (differential) elastic scattering cross-section, by probing a sample to a plurality of depths (by impinging the sample, one at a time, with e-beams of different landing energies), information indicative of the composition of the sample as a function of the depth may be obtained.

Referring to data analysis operation 120, according to some embodiments, and as mentioned above, the set of structural parameters may be obtained as the output of a trained algorithm (i.e. an algorithm derived using machine-learning (ML) tools, also referred to as “ML-derived algorithm”), such as a (trained) neural network (NN), or, according to some embodiments, a (trained) linear model-incorporating algorithm. The algorithm is configured to receive as an input the measured set of electron intensities \vec{I}ₘₛᵣ (obtained in measurement operation 110), optionally, after initial processing (e.g., at the beginning of data analysis operation 120), as described above. Each of the intensities may be labelled by the landing energy of the respective e-beam. Accordingly, in the one-dimensional case, the number of components of \vec{I}ₘₛᵣ equals the number of landing energies.

Generally, data analysis operation 120 may involve the use of a trained NN to obtain the set of structural parameters. However, when the BSE intensity (i.e., the intensity of backscattered electrons) substantially linearly depends on (each of the one or more) structural parameters, which are to be determined, a trained linear model-incorporating algorithm may be employed instead. It is to be understood that the linear dependence does not have to be absolute but rather it may suffice that the BSE intensity statistically exhibits substantial linear dependence on the structural parameters over the ranges the structural parameters are expected vary (e.g., due to manufacturing imperfections): for example, over [ [symbol] \vec{p} [symbol] −\vec{σ}, [symbol] \vec{p} [symbol] +\vec{σ}]. The vector \vec{p} specifies the set of structural parameters. The triangular brackets denote averaging over \vec{p}. \vec{σ} is a vector specifying the standard deviations of each of the components of \vec{p}. In this regard, it is noted that whether or not a first parameter statistically exhibits substantial linear dependence on a second parameter(s), over the range(s) the second parameter(s) is expected to vary, depends on the required accuracy to which the second parameter(s) is to be determined. As a non-limiting example, the first parameter may correspond to the intensity of backscattered electrons returned from an inspected sample due to the imping thereof with an e-beam having a landing energy E, and the second parameter(s) may correspond to a structural parameter(s), which is to be determined using method 100. In particular, the same behavior may be considered substantially linear (and therefore approximated as linear) when a first accuracy is required but nonlinear (and therefore not amenable to treatment using a linear model-based algorithm) when a second accuracy, which is higher than the first accuracy, is required.

According to some embodiments, wherein the linear model is configured to receive as an input a set of structural parameters \vec{p}′ and output a set of electron intensities \vec{I}_{LM}(\vec{p}′), the linear model-incorporating algorithm may involve execution of an optimization algorithm (e.g. least squares). According to some such embodiments, the determined set of structural parameters \vec{p} may be obtained as the solution of argmin_{\vec{p}′}∥\vec{I}ₘₛᵣ−\vec{I}_{LM}(\vec{p}′)∥. The double vertical brackets denote a norm (e.g. L²). Each component of \vec{I}_{LM}(\vec{p}′) may be a linear function of one or more of the components of \vec{p}′. Most generally, each component of \vec{I}_{LM}(\vec{p}′) may be a multi-variable function of the components of \vec{p}′. Further, the term “linear model” is to be understood as not limited to linear functions whose weights are determined using least squares. According to some embodiments, other norms may be utilized to fix the weights, such as the L¹ norm or the Mahalanbois distance. According to some embodiments, a regularizing term(s) may be added to the norm ∥\vec{I}ₘₛᵣ−\vec{I}_{LM}(\vec{p}′)∥ to stabilize the solution or as a constraint(s), which reflects some prior knowledge about the behavior of the backscattered electrons and/or the measurement setup (e.g., the electron sensor). As used herein, the terms “linear model” and “linear regression model” are interchangeable.

More specifically, a linear model-incorporating algorithm may be employed in embodiments wherein the measured electron intensities, optionally, after processing (e.g., to account for noise) are expected to exhibit a substantial linear dependence on the structural parameters (at least over the range over which the structural parameters are expected to vary). The linear model (i.e., the linear model-incorporating algorithm or a sub-algorithm thereof) may describe the impact of one or more internal geometry parameters and/or one or more concentration parameters on the BSE radiation. Accordingly, after training the linear model (i.e. learning the dependence of the BSE intensity on the internal geometry parameter(s) and/or the concentration parameter(s)), BSE radiation from an inspected sample may be measured and one or more structural parameters of the inspected specimen may be estimated. In the context of generating a concentration map of a target substance, a linear model-incorporating algorithm may be employed in embodiments wherein the density of the target substance is sufficiently small such that the intensity of the BSE radiation, which is emitted due to the presence of the target substance, exhibits a substantial linear dependence on the density of the target substance. In particular, if the density of the target substance at a depth d is increased by a factor α, the contribution to the BSE intensity (i.e. the intensity of the backscattered electrons), due to the target substance present at the depth d, will substantially increase by the factor α.

Typically, the number of different GTs required for training a linear model may be smaller by one to two orders of magnitude than required for training a NN. To this end, according to some embodiments, wherein the BSE intensities are expected to exhibit a dependence on the (values of the) structural parameters, that is not close to linear, actual GT and associated actual (i.e., measured) BSE intensities, optionally after processing, may be amplified through simulation to obtain a large simulated training set (for training the NN). The Training Methods Subsection below describes ways whereby such an amplification may be accomplished.

As mentioned above, according to some embodiments, the set of structural parameters (e.g., a concentration map) may be obtained as the output of an algorithm, such as an NN or a linear model-incorporating algorithm. The algorithm may be configured receive as an input the measured set of electron intensities (obtained in measurement operation 110) with each of the intensities being labelled by the landing energy of the respectively inducing e-beam.

According to some embodiments, wherein the set of structural parameters specifies a concentration map of a target substance, such that at each map coordinate(s) the density of the target substance is specified to within a respective density range (from a plurality of density ranges), and data analysis operation 120 is implemented using a NN, the NN may be a classification NN. According to some embodiments, wherein the set of structural parameters specifies a concentration map of a target substance, such that at each map coordinate(s) the density of the target substance is specified to within a respective density range, and data analysis operation 120 is implemented using a linear model-incorporating algorithm, the linear model-incorporating algorithm may involve implementing a linear classifier. According to some embodiments, the set of structural parameters may specify a plurality of such concentration maps pertaining to a plurality of target substances. According to some embodiments, the density ranges may be complimentary in the sense of jointly constituting a continuous range of densities.

According to some embodiments, wherein the set of structural parameters specifies a concentration map specifying at each map coordinate(s) a respective substance, which has the highest density about the map coordinate(s) out of some or all substances nominally included in the inspected sample, the NN (when data analysis operation 120 is implemented using a NN) may be a classification NN. According to some embodiments, wherein the set of structural parameters specifies a concentration map specifying at each map coordinate(s) a respective substance having the highest density about the map coordinate(s), the linear model-incorporating algorithm (when data analysis operation 120 is implemented using a linear model-incorporating algorithm) may involve implementing a linear classifier.

According to some embodiments, wherein each of the set of structural parameters is to be determined to a (single) numerical value rather than a range (e.g., when at each map coordinate(s) the concentration map specifies the density of a target substance to a respective numerical value), the NN (when data analysis operation 120 is implemented using a NN) may be a regression NN.

According to some embodiments, wherein data analysis operation 120 is implemented using a NN, the NN may be a deep NN (DNN), such as a convolutional NN (CNN) or a fully connected NN. According to some embodiments, the NN may be a generative adversarial network (GAN). According to some embodiments, wherein the NN is a classification NN, the NN may be a convolutional NN (CNN). According to some embodiments, wherein the NN is a classification NN, the NN may be composed of a variational autoencoder (VAE) and a classifier (for example, a support vector machine (SVM) or a deep NN). In such embodiments, the measured set of electron intensities (optionally, following initial processing)—without labelling—may be input into the VAE, which is configured to extract therefrom latent variables. The latent variables, each labelled by the respective landing energy, serve as inputs to the classifier, which is configured to output the (determined) set of structural parameters (e.g., the concentration map). Alternatively, according to some embodiments, the NN may be a multi-head VAE. According to some embodiments, wherein the NN is a classification NN, the NN may be an AlexNet, a VGG NN, or a ResNet.

The Training Methods Subsection below describes various ways whereby an algorithm, such as a NN, may be trained to determine a set of structural parameters of an inspected sample from a measured set of electron intensities of the inspected sample, which pertains to a plurality of e-beam landing energies (i.e., landing energies of the e-beams), respectively.

FIG. 3 presents a flowchart of a method 300 for three-dimensional depth-profiling of samples. Method 300 corresponds to specific embodiments of method 100. Method 300 includes:
A measurement operation 310, wherein, for each (integer) k from 1 to N_{\vec{L}}, and for each of a respective plurality of landing energies of e-beams (that is, different k may have associated therewith different pluralities of landing energies, respectively, which may differ in values and in number), a respective set of measured set of electron intensities is obtained by:
   A suboperation 310a, wherein an e-beam is projected on an inspected sample on a k-th lateral location thereon, so as to penetrate into the inspected sample and induce backscattering of electrons from a respective volume (also referred to as “probed region”) of the inspected sample at a depth, which is determined by the landing energy of the e-beam.
   ▪A suboperation 310b, wherein an intensity of scattered electrons (e.g. backscattered electrons) returned from the inspected sample is measured.
A data analysis operation 320, wherein a set of structural parameters of the inspected sample is determined based on the measured sets of electron intensities (i.e. the totality of measurement data obtained by sensing electrons in the implementations of suboperation 310b) and taking into account reference data indicative of an intended design of the inspected sample. The set of structural parameters characterizes an internal geometry and/or a (material) composition of the inspected sample.

The skilled person will readily perceive that the order at which the above operations and suboperations are listed is not unique. Other applicable orders are also covered by the present disclosure. For example, according to some embodiments, data analysis operation 320 may be commenced prior to the conclusion of measurement operation 310.

Method 300 may be implemented using a system, such as the system described below in the description of FIG. 6, according to some embodiments thereof, or a system similar thereto.

According to some embodiments, the set of structural parameters specifies a three-dimensional concentration map of a target substance included in the inspected sample. The skilled person will perceive that method 300 may also be employed to obtain a two-dimensional (defined by the depth dimension and a lateral dimension) concentration map of a target substance in an inspected sample.

According to some embodiments, the set of structural parameters specifies a two-dimensional map that maps lateral variations in the average concentration (wherein the average is taken over the depth dimension) of a target substance included in the inspected sample. According to some embodiments, the set of structural parameters specifies a two-dimensional map that specifies at each pair of lateral map coordinates the substance having the highest average concentration (wherein the average is taken over the depth dimension) out of all substances included in the inspected sample or a predefined set thereof. According to some embodiments, wherein the inspected sample is layered, the set of structural parameters specifies a two-dimensional map that maps lateral variations in the thickness of a layer of the inspected sample.

According to some embodiments, wherein a three-dimensional concentration map of the inspected sample is to be generated, in data analysis operation 320, the measured sets of electron intensities may be subject to an integrated analysis: In addition to a measured set of electron intensities, which pertains to a first lateral location, other measured sets of electron intensities, which pertain to other lateral locations are additionally taken into account in determining the map properties beneath the first lateral location. As a non-limiting example, to determine the density distribution of a target substance beneath a first lateral location, in addition to a measured set of electron intensities pertaining to the first lateral location, other measured sets of electron intensities, which pertain to a plurality of lateral locations that are nearest neighbor to the first lateral location, may additionally be taken into account. Accordingly, in measurement operation 310, according to some embodiments, the density of the Ni lateral locations may be dictated by the required lateral resolution(s) of the concentration map. According to some embodiments, prior to being subjected to the integrated analysis, the measured set of electron intensities may undergo initial processing, e.g. as described above with respect to data analysis operation 120.

Suboperation 310b may be implemented using one or more electron sensors (e.g., which may constitute or form part of an electron sensor, such as the electron sensor of FIG. 6). According to some embodiments, the electron sensor is an electron image sensor (e.g. a BSE image detector). In such embodiments, each of the sensed electrons data sets includes at least the measured intensities of electrons incident on each pixel on the electron image sensor in the respective implementation of suboperation 310b. According to some embodiments, suboperation 310b may be implemented using two or more electron sensors and/or electron image sensors. In such embodiments, each of the measured sets of electron intensities includes at least the intensities of the electrons measured by each of the electron sensors, or by each pixel on each of the electron image sensors, in the respective implementation of suboperation 310b.

It is noted that method 300 may be used to validate the density distributions of one or more substances within a sample, essentially as described above in the description of method 100.

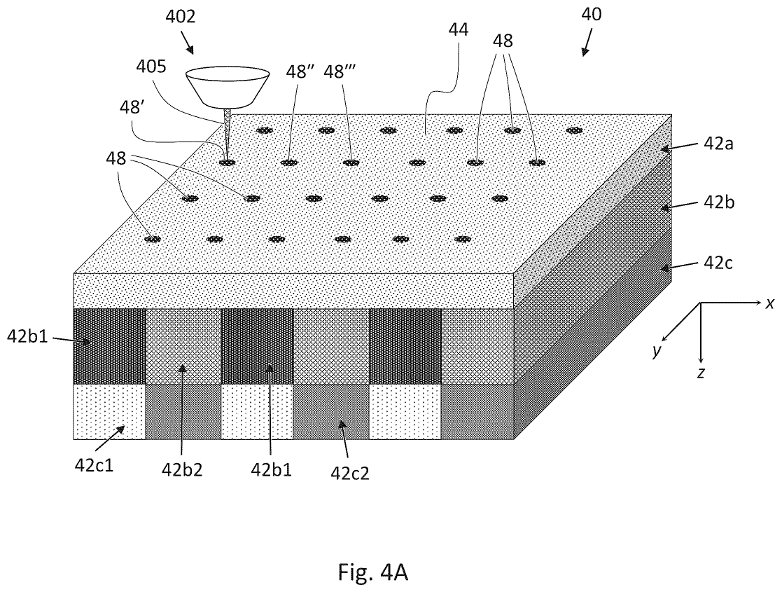

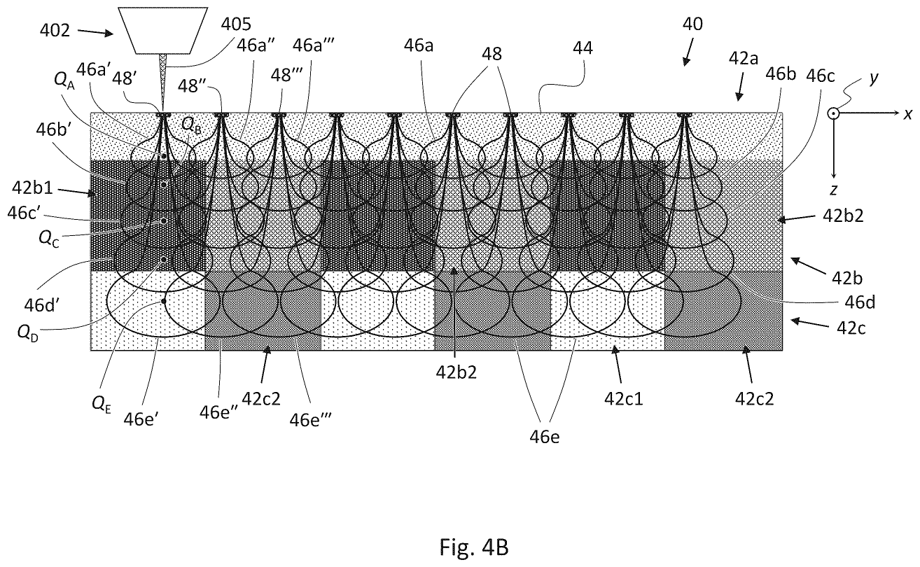

To facilitate the description, in addition to FIG. 3, reference is also made to FIGS. 4A and 4B, which schematically depict an implementation of method 300, according to some embodiments thereof. FIG. 4A shows a perspective view of a sample 40 being probed by an e-beam in accordance with measurement operation 310. Sample 40 may include a plurality of layers 42. To facilitate the description, it is assumed that at least some of layers 42 differ from one another in (material) composition. According to some embodiments, at least some of layers 42 may differ from one another in dimensions thereof. According to some embodiments, at least some of layers 42 may differ from one another in internal geometries thereof. According to some embodiments, at least some of layers 42, which include the same constituents (i.e., substances), differ from one another in the distributions of the constituents therein. According to some such embodiments, wherein layers 42 are shaped, or nominally shaped, as horizontally disposed slabs, at least some of layers 42 may differ from one another in thickness.

As a non-limiting example, in FIG. 4A sample 40 is shown as including three layers disposed one on top of the other: a first layer 42a (from layers 42), a second layer 42b (from layers 42), and a third layer 42c (from layers 42). First layer 42a is disposed above second layer 42b. Second layer 42b is sandwiched between first layer 42a and third layer 42c. The top surface of first layer 42a constitutes an external surface 44 of sample 40.

As depicted in FIGS. 4A and 4B, second layer 42b may be non-uniform by design and may include two types of segments: first segments 42b1 and second segments 42b2 (not all of which are numbered in FIGS. 4A and 4B). Each of first segments 42b1 and each of second segments 42b2 extends in parallel to the y-axis. First segments 42b1 and second segments 42b2 are alternately disposed. According to some embodiments, first segments 42b1 differ from second segments 42b2 in the composition thereof, whether in terms of constituents (i.e., substances included therein) and/or densities of same constituents. According to some embodiments, first segments 42b1 may be composed of a first semiconductor material (i.e., semiconductor substance) and second segments 42b2 may be composed of a second semiconductor material.

Similarly, and as depicted in FIGS. 4A and 4B, third layer 42c may be non-uniform by design and may include two types of segments: third segments 42c1 and fourth segments 42c2 (not all of which are numbered in FIGS. 4A and 4B). Each of third segments 42c1 and each of fourth segments 42c2 extends in parallel to they-axis. Third segments 42c1 and fourth segments 42c2 are alternately disposed. According to some embodiments, third segments 42c1 differ from fourth segments 42c2 in the (material) composition thereof, whether in terms of constituents and/or densities of same constituents. According to some embodiments, third segments 42c1 may be composed of a third semiconductor material and fourth segments 42c2 may be composed of a fourth semiconductor material. According to some embodiments, and as depicted in FIGS. 4A and 4B, third segments 42c1 are positioned below first segments 42b1, respectively, and fourth segments 42c2 are positioned below second segments 42b2, respectively.

Also shown is an e-beam source 402. E-beam source 402 may be configured to project e-beams (one at a time) on each of a plurality of (lateral) locations 48 (not all of which are numbered) on external surface 44. For example, in FIG. 4A e-beam source 402 is shown generating an e-beam 405, which impinges (e.g., normally impinges) on external surface 44 at a location 48′ (from locations 48). At least some of the e-beams projected on the same location differ from one another in landing energy, so that sample 40 is probed (beneath location 48′) at a plurality of depths. According to some embodiments, locations 48 may be so distributed so as to define a lattice, for example, a square lattice.

Referring also to FIG. 4B, FIG. 4B presents a cross-sectional view of sample 40 that shows probed regions 46 therein, according to some embodiments of method 300, and, in particular, measurement operation 310. As a non-limiting example intended to facilitate the description by making it more concrete, in FIG. 4B at each of locations 48 e-beams at five landing energies are applied. According to some embodiments, each of probed regions 46a corresponds to a respective volume from which about all (e.g. at least 80%, at least 90%, or at least 95%) of the backscattered electrons are reflected as a result of the penetration of a respective e-beam at a respective first landing energy into sample 40 via a respective location from locations 48. For example, a first probed region 46a′ corresponds to the volume from which about all of the backscattered electrons are reflected as a result of the penetration of an e-beam at a first landing energy E₁′ into sample 40 via a location 48′ (from locations 48).

Each of probed regions 46b corresponds to a respective volume from which about all of the backscattered electrons are reflected as a result of the penetration of a respective e-beam at a respective second landing energy (greater than the respective first landing energy) into sample 40 via a respective location from locations 48. For example, a second probed region 46b′ corresponds to the volume from which about all of the backscattered electrons are reflected as a result of the penetration of an e-beam at a second landing energy E₂′>E₁′ into sample 40 via location 48′.

Each of probed regions 46c corresponds to a respective volume from which about all of the backscattered electrons are reflected as a result of the penetration of a respective e-beam at a respective third landing energy (greater than the respective second landing energy) into sample 40 via a respective location from locations 48. For example, a third probed region 46c′ corresponds to the volume from which about all of the backscattered electrons are reflected as a result of the penetration of an e-beam at a third landing energy E₃′>E₂′ into sample 40 via location 48′.

Each of probed regions 46d corresponds to a respective volume from which about all of the backscattered electrons are reflected as a result of the penetration of a respective e-beam at a respective fourth landing energy (greater than the third landing energy) into sample 40 via a respective location from locations 48. For example, a fourth probed region 46d′ corresponds to the volume from which about all of the backscattered electrons are reflected as a result of the penetration of an e-beam at a fourth landing energy E₄′>E₃′ into sample 40 via location 48′.

Each of probed regions 46e corresponds to a respective volume from which about all of the backscattered electrons are reflected as a result of the penetration of a respective e-beam at a respective fifth landing energy (greater than the fourth landing energy) into sample 40 via a respective location from locations 48. For example, a fifth probed region 46e′ corresponds to the volume from which about all of the backscattered electrons are reflected as a result of the penetration of an e-beam at a fifth landing energy E₅′>E₄′ into sample 40 via location 48′.

First probed region 46a′ is centered about a first point Q_{A} at a depth b_{A}, second probed region 46b′ is centered about a second point Q_{B} at a depth b_{B}, third probed region 46c′ is centered about a third point Q_{C} at a depth b_{C}, fourth probed region 46d′ is centered about a fourth point Q_{D} at a depth b_{D}, and fifth probed region 46e′ is centered about a fifth point QE at a depth b_{E}. E₁<E₂′<E₃′<E₄′<E₅′. Accordingly, b_{A}<b_{B}<b_{C}<b_{D}<b_{E}. According to some embodiments, and as depicted in FIG. 4B, fifth probed region 46e′ is of a greater size than fourth probed region 46d′, which is of a greater size than third probed region 46c′, which is of a greater size than second probed region 46b′, which is of a greater size than first probed region 46a′.

Also indicated are a location 48″ and a location 48′″ (from locations 48). Each of locations 48′ and 48′″ is adjacent to location 48″, which is positioned there between. A probed region 46a″, from probed regions 46a, corresponds to the volume from which about all of the backscattered electrons are reflected as a result of the penetration of an e-beam at a respective first landing energy into sample 40 via location 48″. A probed region 46e″, from probed regions 46e, corresponds to the volume from which about all of the backscattered electrons are reflected as a result of the penetration of an e-beam at a respective fifth landing energy into sample 40 via location 48″. A probed region 46a′″, from probed regions 46a, corresponds to the volume from which about all of the backscattered electrons are reflected as a result of the penetration of an e-beam at a respective first landing energy into sample 40 via location 48′″. A probed region 46e′″, from probed regions 46e, corresponds to the volume from which about all of the backscattered electrons are reflected as a result of the penetration of an e-beam at a respective fifth landing energy into sample 40 via location 48′″.

It is noted that since sample 40 is not uniform along the direction defined by the x-axis, sets of landing energies of e-beams applied at locations which differ in their x-coordinates may differ. Thus, for example, since location 48′ is positioned above one of first segments 42b1 and one of third segments 42c1, while location 48′″ is positioned above one of second segments 42b2 and one of fourth segments 42c2, according to some embodiments, {E′″ᵢ}ᵢ₌₁⁵≠{E′ᵢ}ᵢ₌₁⁵. {E′″ᵢ}ᵢ₌₁⁵ is the set of landing energies corresponding to e-beams applied via location 48′″ (and {E′ᵢ}ᵢ₌₁⁵ is the set of landing energies corresponding to e-beams applied via location 48′).

Example embodiments—wherein sets of landing energies may be selected to differ from one another depending on the respective lateral locations on which the e-beams are projected—are when first segments 42b1 are denser than second segments 42b2, so that in order to penetrate first segments 42b1 to the same depth as second segments 42b2, a greater landing energy may be required. If, in addition, third segments 42c1 are denser than fourth segments 42c2, in order to ensure that sample 40 is probed to about the same depth beneath each of location 48′ and 48″, for each i, Eᵢ′ may be greater than Eᵢ′″. Other example embodiments—wherein sets of landing energies may be selected to differ from one another depending on the respective lateral locations on which the e-beams are projected—are when first segments 42b1 and third segments 42c1 are less electrically conducting than second segments 42b2 and fourth segments 42c2, respectively.

The distances between adjacent locations from locations 48 (and therefore the distances between the centers of laterally adjacent probed regions) are selected based on the required lateral resolution (which may or may not be equal to the required vertical resolution). It is noted that while in FIG. 4B laterally adjacent probed regions are shown as overlapping, depending on the required lateral resolution, according to some other embodiments, some laterally adjacent probed regions (centered about smaller depths), or even all laterally adjacent probed regions, may not overlap. According to some embodiments, the lateral resolution is selected to be sufficiently high to detect and “pin-point” changes in the concentration of the profiled constituent(s). Accordingly, the distance between adjacent lateral locations (from lateral location 48) may be selected to be smaller than the width of first segments 42b1 as well as the width of second segments 42b2.

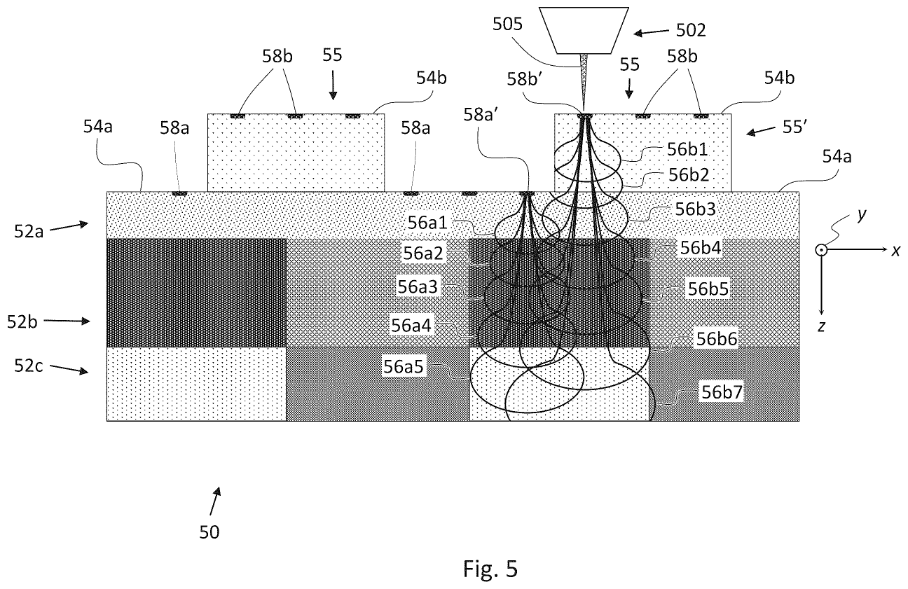

While in FIGS. 4A and 4B external surface 44 is depicted as flat, it is to be understood that method 300 may be applied to samples, which do not have a flat top surface. In particular, method 300 may be applied to samples whose top surface includes areas at different elevations. FIG. 5 depicts an implementation of method 300 to such a sample, a sample 50, according to some embodiments. As a non-limiting example, sample 50 is shown as including a first layer 52a, a second layer 52b, and a third layer 52c, which are disposed one on top of the other. Sample 50 further includes projecting structures 55, which are positioned on top of first layer 51 and project therefrom in the direction of the negative z-axis. Projecting structures 55 jointly have smaller lateral dimensions than first layer 52a, so that a top surface of sample 50, constituted by an external surface 54, includes two (discontinuous) lateral surfaces of different elevation: a first surface 54a and a second surface 54b. First surface 54a constitutes the top external surface of first layer 52a. Second surface 54b includes the top surfaces of projecting structures 55. According to some embodiments, projecting structures 55 may have a different material composition than any of layers 52a, 52b, and 52c.

Also shown is an e-beam source 502 and an e-beam 505 produced thereby, so as to impinge (e.g. normally impinge) on external surface 54. First lateral locations 58a (not all of which are numbered) on first surface 54a indicate locations at which, in operation 310, e-beams projected by e-beam source 502 strike first surface 54a (so as to probe layers 52a, 52b, and 52c there beneath). Second lateral locations 58b on second surface 54b indicate locations at which, in operation 310, e-beams projected by e-beam source 502 strike second surface 54b (so as to probe projecting structures 55 and layers 52a, 52b, and 52c there beneath). E-beams having a first set of landing energies may be directed at each of first lateral locations 58a, respectively, and e-beams having a second set of landing energies may be directed at each of second lateral locations 58b, respectively. In order to probe sample 50 to the full depth thereof beneath both first surface 54a and second surface 54b and to the same resolution, the second set of landing energies may generally be larger than the first set of landing energies (i.e., the number of landing energies in the second set may generally be greater than the number of landing energies in the first set).

Accordingly, delineated in FIG. 5 are (i) five probed regions 56a1, 56a2, 56a3, 56a4, and 56a5 centered below a lateral location 58a′ from first lateral locations 58a, and (ii) seven probed regions 56b1, 56b2, 56b3, 56b4, 56b5, 56b6, and 56b7 centered below a lateral location 58b′ (from second lateral locations 58b) on a projecting structure 55′ (from projecting structure 55). Probed regions below the rest of first lateral locations 58a and second lateral locations 58b are not delineated. Probed region 56b1 is confined within projecting structure 55′, while probed region 56b2 penetrates into first layer 52a but the center thereof is located in projecting structure 55′. The centers of probed regions 56b3, 56b4, 56b5, 56b6, and 56b7 are located within a respective one of layers 52a, 52b, and 52c.

It is to be understood that the applicability of methods 100 and 300 is not limited to samples including nominally flat layers. Regions differing from one another in (material) composition (whether in terms of constituents or, when including the same constituents. in the concentrations of the constituents) may in principle be arbitrarily shaped. In particular, method 100 may be performed on a sample characterized by continuously varying concentrations as a function of the depth coordinate (i.e., the vertical coordinate), of one or more of the substances included in the sample. Similarly, method 300 may be performed on a sample characterized by continuously varying concentrations as a function of the depth coordinate, and/or one or both of the lateral coordinates, of one or more of the substances included in the sample. Further, the skilled person will readily perceive that method 100, and, particularly, method 300, may be applied to (i.e. performed on) samples including empty cavities and/or holes.

### Depth-Profiling Systems

According to an aspect of some embodiments, there is provided a computerized system for depth-profiling of samples (e.g., patterned wafers and/or semiconductor structures therein or thereon). FIG. 6 schematically depicts such a system, a computerized system 600, according to some embodiments. As will be apparent from the description thereof, system 600 may be used to implement each of methods 100 and 300. In particular, system 600 may be used to validate the (nominal) density distributions of one or more substances in an inspected sample, as described above in the descriptions of systems 100 and 300.

System 600 includes an e-beam source 602 (e.g., an electron gun), an electron sensor 604, processing circuitry 606 (also referrable to as “computer hardware”), and a controller 608. According to some embodiments, system 600 may further include electron optics 612 configured to direct and/or focus an e-beam generated by e-beam source 602, and/or direct electrons (e.g., onto electron sensor 604) scattered from a sample due to the irradiation of the sample with the e-beam. According to some embodiments, and as depicted in FIG. 6, e-beam source 602, electron sensor 604, electron optics 612, and controller 608 may constitute components of a SEM 620. According to some embodiments, system 600 may further include a stage 624 (e.g., a xyz stage) configured to accommodate an (inspected) sample 60 (e.g. a patterned wafer). It is noted that sample 60 does not form part of system 600.

Dotted lines between elements indicate functional or communicational association between the elements.

An e-beam 605, generated by e-beam source 602, is shown incident on sample 60. As a result of the incidence of e-beam 605 on sample 60, and the penetration of e-beam 605 into sample 60, backscattered electrons, as well as secondary electrons, are returned from sample 60. Arrows 615 indicates backscattered electrons, as well as secondary electrons, which are scattered from sample 60 in the direction of electron sensor 604. According to some embodiments, electron sensor 604 may be configured to sense electrons returned at 180° relative to the incidence direction thereof of e-beam 605. An arrow 615a (from arrows 615) indicates electrons, which are returned at 180° relative to the incidence direction of e-beam 605.

According to some embodiments, electron sensor 604 may be a BSE detector, i.e., being configured to sense at least backscattered electrons returned from sample 60. According to some embodiments, electron sensor 604 may be a BSE image detector configured to obtain a BSE image. Electron sensor 604 is configured to relay the data collected thereby to processing circuitry 606 either directly, or optionally (and as depicted in FIG. 6), indirectly via controller 608. According to some embodiments, in addition to electron sensor 604, system 600 may include an additional electron sensor (e.g., a second BSE detector).

According to some embodiments, electron optics 612 may include an electrostatic lens(es) and a magnetic deflector(s), which may be used to guide and manipulate an e-beam generated by e-beam source 602, and/or guide onto electron sensor 604 at least backscattered electrons generated due to the penetration of an e-beam into sample 60.

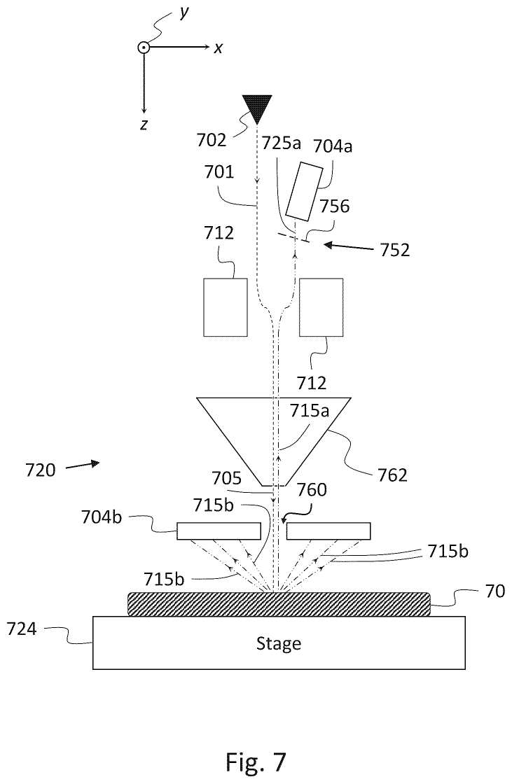

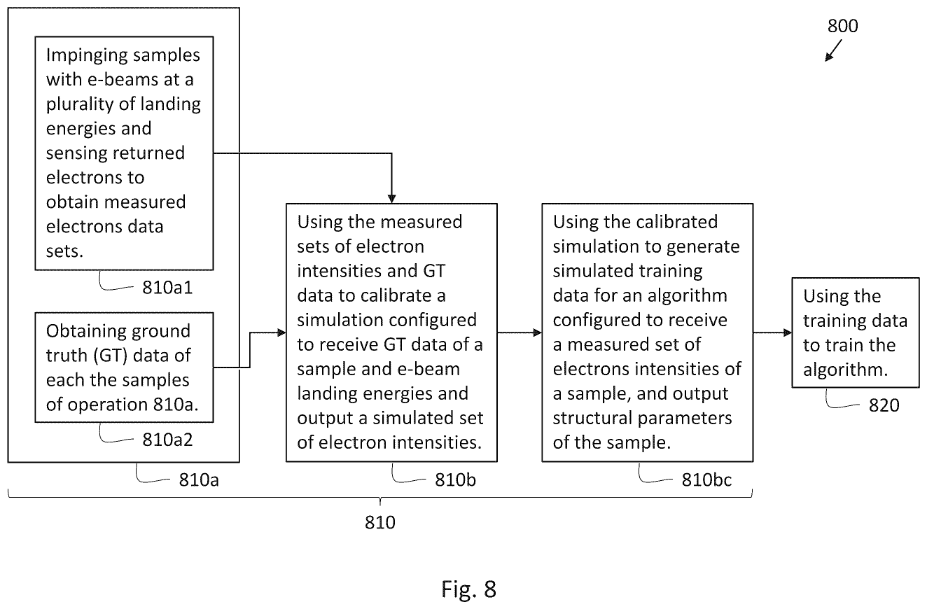

According to some embodiments, electron optics 612 may include an energy filter (not shown) configured to transmit therethrough onto electron sensor 604 electrons having an energy above a threshold energy. More specifically, only electrons with energies higher than the energy threshold pass through the energy filter and reach electron sensor 604, thereby ensuring that substantially only electrons elastically scattered off matter in the sample are sensed by electron sensor 604. A non-limiting example of such a filter, according to some embodiments, is described below in the description of FIG. 7. According to some alternative embodiments, electron optics 612 may include a Wien filter.

According to some embodiments, SEM 620 and stage 624 may be housed within a vacuum chamber 630.

Controller 608 may be functionally associated with e-beam source 602 and, optionally, stage 624. More specifically, controller 608 is configured to control and synchronize operations and functions of the above-listed components of system 600 during probing of an inspected sample. For example, according to some embodiments, wherein stage 624 is movable, stage 624 may be configured to mechanically translate an inspected sample (e.g., sample 60), placed thereon, along a trajectory set by controller 608, thereby allowing for three-dimensional profiling of the inspected sample.

Processing circuitry 606 includes one or more processors (i.e., processor(s) 640), and, optionally, RAM and/or non-volatile memory components (not shown). Processor(s) 640 is configured to execute software instructions stored in the non-volatile memory components. Through the execution of the software instructions, one or more measured sets of electron intensities (e.g., measured by electron sensor 604) of an inspected sample (e.g., sample 60) are processed to determine a set of structural parameters characterizing the inspected sample, essentially as described above in the description of Depth-Profiling Methods Subsection. According to some embodiments, the set of structural parameters specifies a concentration map of the inspected sample. According to some embodiments, at each map coordinate(s) (i.e., in the one-dimensional case, the vertical coordinate, and, in the three-dimensional case, the vertical coordinate and the two lateral coordinates), the concentration map specifies the substance having the highest density about the map coordinate(s), as described above in the Depth-Profiling Methods Subsection. According to some embodiments, at each map coordinate(s), the concentration map specifies the density of a target substance, which is included in the inspected sample. According to some such embodiments, at each map coordinate(s), the concentration map specifies the density of the target substance to within a respective density range, as described above in the Depth-Profiling Methods Subsection. That is, in such embodiments, processing circuitry 606 may be configured to assign the density of the target substance in a subregion about the map coordinate(s) (i.e., the vertical coordinate in the one-dimensional case and the vertical coordinate and two lateral coordinates in the three-dimensional case) to a respective density range from a plurality, or a respective plurality, of (complementary) density ranges. In the one-dimensional case, each of the subregions corresponds to respective thin lateral layer vertically centered about the respective vertical coordinate. In the three-dimensional case, each of the subregions corresponds to a voxel centered about the respective vertical and lateral coordinates. Alternatively, according to some embodiments, at each map coordinate(s), the concentration map specifies the density of a target substance in terms of a (single) numerical value, as described above in the Depth-Profiling Methods Subsection.

According to some embodiments, the set of structural parameters may specify two or more concentration maps specifying the density distributions of two or more target substances, respectively.

According to some embodiments, the set of structural parameters may specify, or additionally specify, one or more of thicknesses of one or more layers of the inspected sample (in some embodiments wherein the inspected sample is layered) and/or overall concentrations (i.e., average densities) of one or more target substances included in the inspected sample.

According to some embodiments, processor(s) 640 may be configured to execute a trained algorithm(s). The trained algorithm(s) is configured to receive as an input a measured set(s) of electron intensities of an inspected sample (e.g., obtained by system 600), optionally, after initial processing of the measured set(s), and to output a concentration map of the inspected sample, as described above in the Depth-Profiling Methods Subsection. According to some embodiments, wherein the trained algorithm is configured to receive the measured set(s) of electron intensities following initial processing thereof, processor(s) 640 may be further configured perform the initial processing. The trained algorithm (e.g., the weights thereof) may depend on reference data indicative of the intended design of the inspected sample, at least in the sense of having been trained using the reference data (e.g., design data and/or GT data) and associated measurement data and/or simulation data. The associated measurement data (e.g., measured sets of electron intensities) may pertain to other samples of the same intended design as the inspected sample, and/or parts of samples of the same intended designs, respectively, as corresponding parts in the inspected sample. The simulation data may be derived from simulating the impinging of (simulated) samples, which are of the same intended design as the inspected sample, with e-beams at each of a plurality of landing energies (e.g., as prescribed by methods 100 and 300).

The intended design may specify the nominal values, or nominal ranges, of geometrical and/or compositional parameters of the inspected sample. According to some embodiments, each measured intensity (in a measured set of electron intensities) may be labelled by the corresponding landing energy. According to some such embodiments, wherein a set of structural parameters, which includes “two-dimensional” and/or “three-dimensional” structural parameters, is to be determined, each measured set of electron intensities may be labelled by the coordinates of the lateral location at which the e-beam impinged on the sample. A non-limiting example of a set of “three-dimensional” structural parameters is provided by a three-dimensional concentration map. A non-limiting example of a set of “two-dimensional” structural parameters is provided by one or more two-dimensional maps specifying the thicknesses of layers in a layered sample as a function of the lateral coordinates.

According to some embodiments, the trained algorithm may be a (trained) NN, such as a DNN (for example, a CNN or a fully connected NN). Alternatively, according to some embodiments, the trained algorithm may be a linear model-incorporating algorithm. The type of algorithm and the architecture thereof may be selected taking into account the intended design of the inspected sample, the ranges over which the structural parameters are expected to vary, and the accuracies to which the structural parameters are to be determined. In this regard it is noted that whether or not the measured BSE intensity exhibits linear dependence on a structural parameter will typically depend on the ranges over which the structural parameter varies: Unless the dependence is purely linear, the greater the range over which a structural parameter varies, the greater may be the deviation from linear dependence. For example, according to some embodiments, wherein lower accuracy suffices and the ranges over which the structural parameters are expected to vary are sufficiently small, a linear model-incorporating algorithm may be employed. In contrast, according to some other embodiments, wherein high accuracy is required, the ranges over which the structural parameters are expected to vary are sufficiently large, and sufficiently large computational resources are available, a NN may be employed.

According to some embodiments, the algorithm may be used in the profiling of samples of different intended designs with the algorithm being configured to receive as inputs—in addition to a measured set(s) of electrons intensities—design data of the inspected sample, and, more generally, according to some embodiments, reference data of the inspected sample.

According to some embodiments, wherein, at each map coordinate(s), the concentration map specifies the substance having the highest concentration (i.e., density), the NN may be a classification NN. According to some such embodiments, the NN may be a CNN, an AlexNet, a VGG NN, a ResNet, or may include a VAE.

According to some embodiments, wherein the concentration map specifies the concentrations of target substances to within density ranges, the NN may be a classification NN. According to some such embodiments, the NN may be a CNN, an AlexNet, a VGG NN, a ResNet, or a VAE (as described in the Depth-Profiling Methods Subsection).

According to some embodiments, wherein the concentration map specifies the density of a target substance in terms of a (single) numerical value, the NN may be a regression NN.

According to some embodiments, e-beam source 602 may be laterally and/or vertically translatable. According to some embodiments, e-beam source 602 may be configured to allow projecting an e-beam at any one of a plurality of incidence angles relative to sample 60. In particular, according to some such embodiments, e-beam source 602 may be configured to allow projecting the e-beam not only perpendicularly to a top surface 64 (i.e., at an incidence angle of 0°) of sample 60 but also obliquely relative thereto (e.g., at an incidence angle of about 10°, about 20°, or about 30°). In such embodiments, the trained algorithm (executable by processing circuitry 606) may be configured to take into account the incidence angles of each of the e-beams in computing the set of structural parameters (e.g., a concentration map).

According to some embodiments, electron sensor 604 (or one or more components thereof) may be laterally and/or vertically translatable, thereby allowing to control the collection angle (i.e. sense backscattered electrons returned from sample 60 at a desired return angle). According to some embodiments, backscattered electrons generated by e-beams of different landing energies may be sensed at different return angles, respectively. In such embodiments, the trained algorithm (executable by processing circuitry 606) may be configured to take into account the return angles of the e-beams in computing the set of structural parameters (e.g., a concentration map).

According to some embodiments, electron sensor 604 may include a plurality of electron sensors, which are configured to sense backscattered electrons at each of plurality of return angles (equivalently, scattering angles). For example, a first electron sensor (e.g., a first BSE detector) may be positioned so as to measure backscattered electrons returned at a scattering angle of about 180°, while a second electron sensor (e.g., a second BSE detector) may be positioned so as to measure backscattered electrons returned at a scattering angle of about 170°, about 160°, or about 150°. In such embodiments, the trained algorithm (executable by processing circuitry 606) may be configured to receive as inputs the intensities of backscattered electrons sensed (measured) by each of the electron sensors, respectively, labelled by the respective return angle.

According to some embodiments, wherein electron optics 612 includes an energy filter, as described above, the trained algorithm (executable by processing circuitry 606) may be configured to receive as an input a measured set of electron intensities, which includes measurement data obtained for different threshold energies of the energy filter. In such embodiments, in addition to being labelled by the landing energy, (at least some of) the measurement data may further be labelled by the threshold energy.

FIG. 7 schematically depicts a SEM 720, according to some embodiments. SEM 720 corresponds to specific embodiments of SEM 620 (of system 600), in which SEM 620 includes two electron sensors. SEM 720 includes an electron gun 702, a first electron sensor 704a, and a second electron sensor 704b. Electron gun 702 corresponds to specific embodiments of electron source 602. Second electron sensor 704b may include a hole 760 for passage therethrough of e-beams prepared by SEM 720. SEM 720 additionally includes a deflection assembly 712 (e.g., including a plurality of magnets and/or magnetic coils). Deflection assembly 712 may be included in, or constitute, electron optics (not all components thereof are shown) of SEM 720, which correspond to specific embodiments of electron optics 612. A controller of SEM 720 is not shown in FIG. 7.

SEM 720 further includes an energy filter 752. Energy filter 752 is configured to filter therethrough electrons with an energy above a selectable threshold energy. According to some embodiments, and as depicted in FIG. 7, energy filter 752 may include at least one electrically conductive grid 756 (i.e., at least one perforated metallic plate) positioned below first electron sensor 704a. Grid 756 may be maintained at a selectable (electric) potential, such that only electrons having an energy above a threshold energy may pass through grid 756 and reach first electron sensor 704a.

Also shown is a stage 724 and a sample 70, which is mounted thereon. Stage 724 and sample 70 correspond to specific embodiments of stage 624 and sample 60, respectively.

According to some embodiments, and as depicted in FIG. 7, in operation, an e-beam 701, generated by electron gun 702, impinges normally on sample 70. E-beam 701 is laterally offset (i.e., laterally displaced) by deflection assembly 712, thereby preparing an incident e-beam 705. Arrows 715 indicate returned electrons (e.g., backscattered electrons), which are produced as a result of the striking of e-beam 705 on sample 70, and, in particular, the penetration thereof thereinto. An arrow 715a (from arrows 715) indicates electrons, which are backscattered at 180° (i.e., electrons that are returned at 180° relative to the incidence direction of e-beam 705). Arrows 715b (from arrows 715) indicate backscattered electrons, which are returned at scattering angles different from 180° and are sensed by second electron sensor 704b.

Electrons backscattered at 180° (i.e., electrons indicated by arrow 715a) pass through deflection assembly 712 and are laterally offset thereby, following which, a portion thereof, indicated by an arrow 725a, is filtered through energy filter 752 and is sensed by first electron sensor 704a. By changing the potential at which grid 756 is maintained, the minimum energy of the electrons in the portion, which is indicated by arrow 725a, is accordingly changed.

SEM 720 is thus seen to be configured to obtain measured sets of electron intensities corresponding to a plurality of scattering angles and which may be “parsed” by the energy of the electrons in the returned e-beams.

According to some embodiments, the electron optics may further include a compound lens 762 configured to focus e-beam 705 on sample 70. To this end, compound lens 762 may include a magnetic lens and an electrostatic lens (not shown). According to some embodiments, second electron sensor 704b may be disposed between compound lens 762 and sample 70.

### Training Methods

According to an aspect of some embodiments, there is provided a method 800 for training an algorithm (e.g., a NN) for depth-profiling, and, more specifically, for implementing data analysis operation 120 of method 100 or data analysis operation 320 of method 300. The algorithm is configured to: (i) receive as an input a measured set of electron intensities pertaining to an inspected sample (e.g., such as sample 60 or 70), optionally, preprocessed, and (ii) output a set of structural parameters characterizing an internal geometry and/or a composition of the inspected sample. Non-limiting examples of sets of structural parameters, which the algorithm is configured to output, are listed above in the Depth-Profiling Methods Subsection and the Depth-Profiling Systems Subsection. Each of the intensities in the measured set of electron intensities is obtained by projecting on the inspected sample an e-beam, at a respective landing energy from a plurality of landing energies, and measuring the intensity of electrons (e.g., backscattered electrons) returned from the inspected sample. According to some embodiments, the algorithm may be configured to receive the measured set of electron intensities following initial processing (i.e., preprocessing) thereof, as described above in the Depth-Profiling Methods Subsection and the Depth-Profiling Systems Subsection. Method 800 may thus be employed to train an algorithm to perform data analysis operation 120 of method 100 or data analysis operation 320 of method 300. Accordingly, the algorithm may be any one of the algorithms described above in relation to methods 100 and 300. As elaborated on below, method 800 is advantageously configured to amplify a small set of pairs of ground truth (GT) data and associated measurement data to obtain a large set of simulated training data for training the algorithm. The GT data may include measured concentration maps of one or more substances in a small plurality of samples. The associated measurement data may include corresponding measured sets of electron intensities (obtained with respect to the plurality of samples), optionally, following initial processing, with each intensity being labelled by the respective landing energy. Method 800 includes:
An operation 810, wherein simulated training data for a (trainable) algorithm (e.g., a NN) are generated by performing:
   A suboperation 810a, wherein calibration data is generated by performing for each sample from Nₛ≥1 samples (also referred to as “GT samples”):
      A suboperation 810a1 of obtaining a measured set of electron intensities, pertaining to the GT sample, by projecting on the GT sample (e.g., one at a time) e-beams at each of a first plurality of landing energies and sensing (e.g., using an electron sensor to measure the intensities of) electrons (e.g. backscattered electrons) returned from the GT sample.
      A suboperation 810a2 of obtaining GT data characterizing the GT sample.
   ▪A suboperation 810b, wherein the calibration data are used to calibrate a computer simulation (e.g., an estimator). The computer simulation is configured to (i) receive as inputs (actual or simulated) GT data of a sample, and (values of) landing energies of e-beams, and (ii) output a corresponding simulated set of electron intensities (i.e., intensities pertaining to each of the landing energies, respectively, obtained through simulation).
   A suboperation 810c, wherein the calibrated computer simulation is used to generate simulated sets of electron intensities corresponding to other samples (i.e., other GTs) and/or additional (e-beam) landing energies.
An operation 820, wherein the algorithm is trained using (at least) the simulated training data.

The calibration data may include the Ns measured sets of electron intensities, optionally, after initial processing (as described above in the Depth-Profiling Methods Subsection and the Depth-Profiling Systems Subsection), and the measured GT data of the Ns GT samples. More specifically, the calibration data may include measured data sets pertaining to each of the Ns GT samples of suboperation 810a. Each measured data set includes the measured GT data pertaining to one of the Ns GT samples, and the respective measured set of electron intensities (optionally, after initial processing) with the intensities being labelled by the landing energies of the respectively inducing e-beams. It is noted that GT data may be richer than the set of structural parameters to be output by the algorithm (which is to be trained). For example, according to some embodiments, wherein the algorithm is configured to output the thicknesses of layers of different compositions, the GT data may specify not only thicknesses of layers in each of the GT samples but also overall concentrations of one or more substances included in each of the layers, respectively. Most generally, the GT data may specify concentration maps of one or more substances, respectively, included in each of the GT samples, and/or any information, which may be obtained using profiling techniques, and, in particular, destructive profiling techniques, and which may serve to improve the calibration of the computer simulation. Non-limiting examples of destructive profiling techniques include profiling techniques involving the use of a SEM and/or a TEM to profile lamellas extracted from the GT samples.

It is noted that in embodiments wherein the algorithm to undergo training is configured to output a concentration map(s) of a target substance(s) included in a sample, in suboperation 810a2, a concentration map of the target substance(s) is obtained. However, according to some embodiments, wherein the algorithm to undergo training is configured to output comparatively less detailed information than specified by a concentration map (e.g., the overall concentration of a substance included in a sample), the GT data may be less detailed.

According to some embodiments, the GT samples include samples of the same intended design, and, in particular, of the same intended design as the samples which the algorithm is trained by method 800 to depth-profile. Additionally, or alternatively, according to some embodiments, at least some of the GT samples may be especially prepared so as to reflect the range of variation of a structural parameter from a selected minimum value of the structural parameter to a selected maximum value thereof.

The simulated training data may include the simulated sets of electron intensities (e.g., of backscattered electrons) and associated sets of structural parameters. Each of the associated sets of structural parameters may be constituted by, or derived from, GT data pertaining to a respective sample. More specifically, the simulated training data may include data sets respectively pertaining to each of a plurality of samples. Each data set includes, as an output set, a set of structural parameters pertaining to one of the samples in the plurality of samples, and, as an input set, the respective simulated sets of electron intensities labelled by the landing energies of the inducing e-beams. Each sample in the plurality of samples may or may not pertain to an actual sample (e.g., one of the Ns GT samples profiled in suboperation 810a). An example of the former case is when the calibrated computer simulation is used to simulate the striking of e-beams on one or more (simulated) samples, which are characterized by the actual GT data measured in suboperation 810a2, with the (simulated) e-beams having different landing energies than those of the e-beams applied in suboperation 810a1. (That is, none of the landing energies of the simulated e-beams are included in the first plurality of landing energies of suboperation 810a1). An example of the latter case is when the calibrated computer simulation is used to simulate the striking of e-beams on one or more (simulated) samples characterized by simulated GT data (e.g., simulated density distributions), which differ from the actual GT data (e.g. actual density distributions) of the Ns GT samples measured in suboperation 810a2.

According to some embodiments, wherein (i) the algorithm is configured to receive as an input a measured set of electron intensities (obtained with respect to a plurality of landing energies) following initial processing thereof, and (ii) the computer simulation is configured to output a set of structural parameters, suboperation 810b may include an initial suboperation wherein the (raw) measured set of electron intensities (obtained in suboperation 810a1) undergoes initial processing. The initial processing may include isolating, or at least amplifying, the contributions to the (raw) measured set of electron intensities, respectively, of the backscattered electrons induced by the projected e-beams, e.g., as described above in the Depth-Profiling Methods Subsection.

According to some embodiments, a ratio of the number of the simulated sets of electron intensities to the number of the measured sets of electron intensities (or, equivalently, Nₛ—the number of GT samples) is between about 100 and about 1,000.

According to some embodiments, the training set may include, in addition to the simulated training data, non-simulated training data. The non-simulated training data may include measured input sets constituted by the measured sets of electron intensities (optionally, following initial processing) obtained in the implementations of suboperation 810a1, and corresponding output sets of structural parameters constituted by, or derived from, the measured GT data obtained in suboperation 810a2. Each intensity in the measured sets of electron intensities may be labelled by the landing energy of the respectively inducing e-beam.

According to some embodiments, the computer simulation of suboperation 810b is tailored to a specific intended design. According to some such embodiments, the computer simulation may be configured to receive as inputs (i) GT data of a sample of the specific intended design, and (ii) the landing energies of e-beams (e.g., simulated e-beams) projected on the sample, and to output a respective (optionally, processed) measured set of electron intensities. Alternatively, according to some embodiments, particularly embodiments wherein in suboperation 810c at least some of the other samples may be of different intended designs, the computer simulation may be configured to additionally receive as an input the intended design of the sample.

According to some embodiments, in suboperation 810b, the computer simulation may be calibrated such that, for each of the Nₛ GT samples, when the respective GT data is input into the computer simulation, the simulated set of electron intensities, output by the computer simulation, agrees to within a required precision with the respective measured set of electron intensities.

According to some embodiments, the algorithm (to be trained using method 800) may be a NN. According to some embodiments, the NN may be a DNN, such as a CNN or a fully connected NN, or may include a VAE and a classifier or a multi-head, as detailed above in the descriptions of methods 100 and 300. According to some embodiments, the NN may be a GAN.

According to some embodiments, the NN may be a classification NN. According to some such embodiments, the NN may be a CNN, an AlexNet, a VGG NN, a ResNet, or may include a VAE. According to some embodiments, wherein the algorithm is configured to generate a concentration map of an inspected sample, the outputs of the classification NN specify, for each map coordinate(s), the substance (from a plurality of substances included in the inspected sample), which has the highest density about the map coordinate(s). Alternatively, according to some embodiments, the outputs of the classification NN specify, for each map coordinate(s), the density of a target substance about the map coordinate(s) to within a respective density range from a plurality of complementary density ranges.

According to some embodiments, the NN may be a regression NN. According to some such embodiments, wherein the algorithm is configured to generate a concentration map of an inspected sample, the outputs of the regression NN specify, for each map coordinate(s), the density of a substance about the map coordinate(s) in terms of respective (single) numerical value.

Suboperation 810a1 may be implemented as specified in the description of measurement operation 110 of method 100, and suboperation 310 of method 300, in the Depth-Profiling Methods Subsection above. In particular, the use of e-beams of different landing energies allows obtaining (measured) intensities of backscattered electrons originating from different volumes (i.e., probed regions of the sample), which are centered about different depths, respectively.

Suboperation 810a2 may be implemented by profiling lamellas extracted from each of the Nₛ GT samples and/or slices shaved there off. According to some embodiments, the profiling may be performed using a SEM and/or a TEM.

According to some embodiments, the output of the algorithm is a three-dimensional concentration map of an inspected sample, and the measured GT data, obtained in the Nₛ implementations of suboperation 810a2, specify, include, or are indicative of three-dimensional concentration maps of one or more substances included in each of the Nₛ GT samples. In such embodiments, (i) in each implementation of suboperation 810a1, the e-beams may be projected on the respective GT sample at each of a plurality of lateral locations thereon, and (ii) in suboperation 810c the simulated sets of electron intensities, whether raw or processed, may be generated for each of the plurality of lateral locations. According to some such embodiments, in operation 820 each of the simulated sets of electron intensities, whether raw or processed, used as inputs in training the algorithm, is further labelled by the lateral location at which the respective (simulated) e-beams impinge on the respective sample.

According to some embodiments, the algorithm is configured to output (a) one or more two-dimensional maps specifying the lateral variations in the thicknesses of layers in a layered sample, and/or (b) one or more two-dimensional maps specifying lateral variations in the average concentrations (averaged over the vertical dimension) of one or more target substances included in a sample. In such embodiments, (i) in each implementation of suboperation 810a1, the e-beams may be projected on the respective GT sample at each of a plurality of lateral locations thereon, and (ii) in suboperation 810c the simulated sets of electron intensities, whether raw or processed, may be generated for each of the plurality of lateral locations. According to some such embodiments, in operation 820 each of the simulated sets of electron intensities, whether raw or processed, used as inputs in training the algorithm, is further labelled by the lateral location at which the respective (simulated) e-beams impinge on the respective sample.

According to some embodiments, the calibration of the computer simulation involves calibration of point spread functions (PSFs). According to some such embodiments, a modified Richardson-Lucy algorithm may be applied to obtain calibrated PSFs from initial PSFs (thereby calibrating the computer simulation).

More specifically, according to some embodiments, initially, i.e. prior to the calibration of the computer simulation in suboperation 810b, the computer simulation specifies a set of initial point spread functions (PSFs)

$$( PSFs ) {\{ {H}_{E}^{( i )} \}}_{E} = \{ {H}_{{E}_{1}}^{( i )} , {H}_{{E}_{2}}^{( i )} , ... , {H}_{{E}_{{N}_{E}}}^{( i )} \} ,$$

wherein N_{E} is the number of landing energies. (An index on curly brackets, which denote a set, is used herein to indicate that the index is generally a running index.) Each of the H_{E}⁽ⁱ⁾ corresponds to a respective landing energy (as indicated by the subscript E) from a set of landing energies, which includes the first plurality of landing energies, and, optionally, other landing energies. For each landing energy E, the corresponding initial PSF specifies, as a function of the depth within the sample, the intensity of electrons (as determined by the computer simulation), which will be (a) scattered (e.g. elastically backscattered), per particle or unit mass, due to the penetration of the respective e-beam (i.e. having the landing energy E), and (b) detected by the electron sensor (e.g. a BSE detector) employed. In the three-dimensional case, to each landing energy, and lateral location at which the e-beam impinges on the sample, corresponds an initial PSF, which is a function not only of the depth coordinate within the sample but also of the horizontal coordinates therein.

The set of initial PSFs may be obtained by a second computer simulation. The computer simulation models the striking and penetration of e-beams into a simulated sample and the elastic interactions of electrons in the e-beam with matter in the simulated sample. The simulated sample is of a same design as the intended design of the samples, which are to be depth-profiled using method 100 (or method 300). In suboperation 810b, each in the set of initial PSFs {H_{E}⁽ⁱ⁾}_{E} is calibrated, thereby obtaining a set of calibrated PSFs {H_{E}^{(c)}}_{E}. The superscripts i (for “initial”) and c (for “calibrated”) serve to distinguish between the two sets. The {H_{E}^{(c)}}_{E} are used to generate the simulated sets of electron intensities. In particular, according to some embodiments, the {H_{E}^{(c)}}_{E} may be used to obtain from “simulated” GT data the simulated sets of electron intensities. The simulated GT data may constitute slight variations on the GT data obtained in the Nₛ implementations of suboperation 810a2.

It is noted that in the one-dimensional case (i.e., when a one-dimensional concentration map of a sample is to be obtained and uniformity along lateral directions may be assumed at least over a small range of a few micrometers), each of the initial and calibrated PSFs will depend on the depth z and the (one-dimensional, e.g., particle) density ρ(z). More specifically, H_{E}(ρ(z), z) gives the contribution of the target substance at the coordinate z to the intensity of backscattered electrons (produced as a result of impinging the sample with an e-beam at a landing energy E). Generally, H_{E},(ρ(z),z)) may be highly non-linear in the density ρ over a region of an inspected sample, which is to be profiled. In such embodiments, in order to derive H_{E}^{(c)}(ρ(z), Z), H_{E}⁽ⁱ⁾(ρ(z), z) is “piecewise linearized” in the sense of being approximated as a sum of linear functions of the density ρ having support over distinct and complimentary intervals of z.

More precisely, the sample (or a part thereof which is to be profiled) may be “broken up” into segments over each of which H_{E}⁽ⁱ⁾ (ρ(z), z) substantially exhibits linearity. It is noted that generally the segments may differ in thickness. Further, the thicknesses of the segments may vary depending on the landing energy E. For the sake of simplicity, in the following it is assumed that for each landing energy the sample is broken up into K segments Δzₖ=(zₖ₋₁, zₖ) with zₖ₋₁<zₖ, 1≤k≤K, z₀=0, and z_{K}=zₘₐₓ. Accordingly, and assuming that the concentration of the target substance is sufficiently small, for each k, over the k-th interval H_{E}(ρ(z), z)→H_{E, k}(z)·ρ(z). For each k, the respective PSF—that is, H_{E, k}(z)—is non-vanishing only over the k-th interval (i.e. H_{E, k}(z)=0 for z<zₖ₋₁ and z >zₖ). Accordingly, for each landing energy E of the e-beam K initial PSFs (i.e. the set {H_{E, k}⁽ⁱ⁾(z)}ₖ₌₁^{K}) are calibrated. More generally, when the concentration of the target substance is larger, for each k, over the k-th interval, H_{E}(ρ(z), z) →H_{E, k}⁽⁰⁾(z)+H_{E, k}⁽¹⁾(z)·Δρₖ(z). Here Δρₖ(z) quantifies spatial fluctuations about a baseline concentration in the k-th interval Δzₖ.

As a non-limiting example, assuming that the measured intensities of the scattered electrons are Gaussian-distributed, in the linear regime, the probability of measuring an intensity I_{E}, given the actual (i.e. true to the required accuracy) H_{E, k}(z), is given by: p(I_{E}|{H_{E, k}(z)}ₖ₌₁^{K}, ρ(z))∝exp [− [symbol] (I_{E}−∫₀^{z}^{ₘₐₓ} dz ρ(z)·EₖH_{E, k}(z))²]. [symbol] is a normalization factor.

{H_{E, k}⁽ⁱ⁾(z)}ₖ₌₁^{K} is expected to maximize the likelihoods p(I_{E, s}|{H_{E, k}⁽ⁱ⁾(z)}ₖ₌₁^{K}, ρₛ(z). The added subscript s denotes the GT sample (from the Nₛ GT samples of suboperation 810a). The I_{E, s} are the intensities, measured in the Nₛ implementations of suboperation 810a1, and the ρₛ(z) are densities of the target substance in each of the Nₛ GT samples, respectively. Discretizing the H_{E, k}(z), so that for each k H_{E, k}(z) is approximated by the average thereof over Δzₖ H_{E, k}= [symbol] H_{E, k}(z) [symbol] _{Δz}_{ₖ}, the H_{E, k}^{(c)}(z) (or, more precisely, the discretization thereof Ĥ_{c}) may be deduced by solving the optimization problem (Eq. 1): Ĥ_{c}=argmin_{Ĥ}(∥Ĥ_{\hat{ρ}}−Î∥_{F}²+γ∥Ĥ−Ĥᵢ∥_{F}²). Here Ĥ is a N_{E}×K matrix, wherein N_{E} is the number of landing energies. That is, the rows of Ĥ are constituted by the \vec{H}_{E}, wherein, for each landing energy E, \vec{H}_{E}=(H_{E, 1}, H_{E, 2}, . . . , H_{E, K}) (H_{E, k}= [symbol] H_{E, k}(z) [symbol] _{Δz}_{ₖ}). The hat symbol is used herein to indicate matrices. \hat{ρ} is a K×Nₛ matrix, so that Ĥ_{\hat{ρ}} is a N_{E}×Nₛ matrix. For each 1≤j≤Nₛ, the j-th column of \hat{ρ} specifies averaged values of the density of the target substance in the j-th GT sample about each of the K depths, i.e. for each j and k, the (j, k)-th component of \hat{ρ} equals [symbol] ρⱼ(z) [symbol] _{Δz}_{ₖ} (ρⱼ(z) being the density of the target substance in the j-th GT sample). Î is a N_{E}×Nₛ matrix. For each 1≤j≤Nₛ, the j-th column of Î specifies the (overall) intensities of the scattered electrons for each of the plurality of landing energies, respectively, measured in the implementations of suboperation 810a1 when applied with respect to the j-th GT sample. The rows of Ĥᵢ are constituted by the (row) vectors \vec{H}_{E}⁽ⁱ⁾, which are obtained by discretizing the H_{E, k}⁽ⁱ⁾(z). (For each landing energy E, \vec{H}_{E}⁽ⁱ⁾=(H_{E, 1}⁽ⁱ⁾, H_{E, 2}⁽ⁱ⁾, . . . , H_{E, K}⁽ⁱ⁾), wherein for each k H_{E, k}⁽ⁱ⁾= [symbol] H_{E, k}⁽ⁱ⁾(z) [symbol] _{Δz}_{ₖ}.) The subscript F indicates the Frobenius norm. γ is a hyperparameter whose value may be “manually” adjusted to optimize, or at least improve, the estimate of Ĥ (and thereby of the H_{E}(z)). Similarly, the degree of discretization (i.e., the magnitude of K) may be selected based on the required accuracy. The optimization problem may be solved iteratively, e.g., using a modified Richardson-Lucy algorithm, wherein, as a first approximation Ĥ is taken to equal Ĥᵢ. According to some embodiments, N_{E}≥K.

It is noted that the above optimization problem is underdetermined, and so has no unique solution. There is thus no absolute guarantee that the deduced H_{E}^{(c)}(z) will closely match the actual H_{E}(z). Nevertheless, if the initially simulated PSFs (i.e., the H_{E}⁽ⁱ⁾(z)) are sufficiently close to the actual H_{E}(z), the solution of the optimization problem will likely closely match the actual H_{E}(z).

If more than one substance is to be profiled, then the above optimization procedure may be carried out with respect to each of the profiled substances. Examples include (i) when the trained algorithm is to output a concentration map specifying about each map coordinate(s) the substance having the highest density, or (ii) when the trained algorithm is to output two or more concentration maps specifying the density distributions of two more target substances, respectively, which are included in an inspected specimen.

In the three-dimensional case (e.g. when a three-dimensional concentration map of a profiled substance in a sample is to be obtained), the optimization problem (Eq. 1) may be solved with Ĥ, \hat{ρ}, and Î generalized to three-dimensions. More specifically, each of the PSFs is a three-variable function and is further indexed by the coordinates \vec{L}=(Lₓ, L_{y}) of the lateral location on which the respective e-beam struck (i.e., impinged on) the sample. Accordingly, in such embodiments, in suboperation 810c: {H_{E, \vec{L}}⁽ⁱ⁾(ρ(\vec{r}), \vec{r})}_{E, \vec{L}}→{H_{E, \vec{L}}^{(c)}(ρ(\vec{r}), \hat{r})}, wherein \vec{r}=(x, y, z) and ρ(\vec{r}) denotes the density of the profiled substance as a function of \vec{r}.

According to some embodiments, in order to derive the H_{E, \vec{L}}^{(c)}(ρ(\vec{r}), \vec{r}), the sample, or a part thereof which is to be depth-profiled, may be “broken up” into small volumes over each of which H_{E, \vec{L}}⁽ⁱ⁾(ρ(\vec{r}), \vec{r}) exhibits substantial linearity. For the sake of simplicity, in the following it is assumed that for each (e-beam) landing energy E and e-beam striking location \vec{L} the profiled region is broken up into K=Kₓ×K_{y}×K_{z} volumes ΔV_{\vec{k}}. For each \vec{k}=(kₓ, k_{y}, k_{z}), the volume Δ_{\vec{V}k} is defined by intervals Δxₖ_{ₓ}=(xₖ_{ₓ}₋₁, xₖ_{ₓ}) in x, Δxₖ_{_{y}}(xₖ_{_{y}}₋₁, xₖ_{_{y}}) in y, and Δzₖ_{_{z}}=(xₖ_{_{z}}⁻¹, xₖ_{_{z}}), wherein 1≤kₓ≤Kₓ, 1≤k_{y}<K_{y}, and 1≤k_{z}≤K_{z}. Accordingly, for each landing energy E and e-beam striking location \vec{L}, K initial PSFs (i.e. the set {H_{E, \vec{L}, \vec{k}}(z)}_{\vec{k}},) are calibrated).

For each E and L, the H E L, k (f)) may be approximated by a K component (row) vector \vec{H}_{E, \vec{L}}, with K components H_{E, \vec{L}, \vec{k}}= [symbol] H_{E, \vec{L}, \vec{k}}(\vec{r}) [symbol] Δv_{\vec{k}}· [symbol] H_{E, \vec{L}, \vec{k}}(\vec{r}) [symbol] Δv_{\vec{k}} is the average of H_{E, \vec{L}, \vec{k}}(\vec{r}) taken over the volume ΔV_{\vec{k}} defined by kₓ-th interval in x, the k_{y}-th interval in y, and the k_{z}-th interval in z. The rows of \vec{H} are constituted by the H_{E, \vec{L}}. Accordingly, Ĥ is a (N_{E}·N_{\vec{L}})×K matrix, wherein N_{\vec{L}} is the number of e-beam striking locations on the sample. \hat{ρ} is now a K×Nₛ matrix (of averaged values of the densities ρₛ(r) in each of the volumes ΔV_{\vec{k}}), so that Ĥ\hat{ρ} is a (N_{E}·N_{\vec{L}})×Nₛ, matrix. Î is a (N_{E}·N_{\vec{L}})×Nₛ, matrix. For each 1≤j≤Nₛ, the j-th column of Î specifies the intensity of the sensed electrons—per each of the N_{\vec{L}} impinged locations and each of the plurality of landing energies—detected in suboperation 810a when profiling the j-th GT sample. According to some embodiments, N_{E}·N_{\vec{L}}>K.

According to some embodiments, in suboperation 810c, the other samples are of different intended designs than the Nₛ GT samples of suboperation 810a.

According to some embodiments, suboperations 810b and 810c and operation 820 may reapplied when relevant new calibration data become available. More specifically, even after the algorithm has been trained (and can be used to implement data analysis operation 120 of method 100), as new calibration data—particularly, pertaining to new design intents—become available, suboperations 810b and 810c and operation 820 may be reapplied to expand the applicability of method 100 and/or improve the accuracy thereof. Non-limiting examples of new design intents, which may be pertinent, include new internal geometries and/or different concentrations of constituents, and, optionally, inclusion of new constituents (e.g. which are not nominally included in the Nₛ GT samples).

According to some embodiments, wherein, in suboperation 810c, the simulated sets of electron intensities are generated for, or also for, other samples, in operation 820, each of the simulated electrons data sets, used as inputs in training the algorithm, is further labelled by the other sample with respect to which the simulated electrons data were obtained. The other samples are characterized by other GTs than the GTs of the GT samples of operation 810a or even different intended designs.

According to some embodiments, operation 820 includes an initial training suboperation, which may be unsupervised, in which latent variables, which characterize the simulated electrons data sets, are extracted.

According to some alternative embodiments, Ĥᵢ may be calibrated using a U-Net deep learning NN. That is, Ĥ_{c}=U_{F}(θ)⊚Ĥᵢ, wherein U_{F}(θ)—the U-Net—is a CNN and the symbol ∘ denotes the application of U_{F}(θ) on Ĥᵢ. θ denotes a set of adjustable parameters of the U-Net. U_{F}(θ) is obtained from constraints imposed on the measured GT data and associated measured sets of electron intensities, which can be compactly expressed as Î=(U_{F}(θ)∘Ĥᵢ) \hat{ρ}. It is noted that since U_{F}(θ) is nonlinear, unlike the above-described maximum-likelihood based calibration approach, the H_{E, λ}⁽ⁱ⁾(ρ(z), z)—from which Ĥᵢ is obtained through discretization—need not be broken up into segments over which linear behavior is exhibited.

According to some embodiments, the terms “concentration map” and “density distribution” may be used interchangeably.

As used herein, the terms “measuring” and “sensing” are used interchangeably.

In the description and claims of the application, the words “include” and “have”, and forms thereof, are not limited to members in a list with which the words may be associated.

As used herein, the term “about” may be used to specify a value of a quantity or parameter (e.g., the length of an element) to within a continuous range of values in the neighborhood of (and including) a given (stated) value. According to some embodiments, “about” may specify the value of a parameter to be between 80% and 120% of the given value. For example, the statement “the length of the element is equal to about 1 m” is equivalent to the statement “the length of the element is between 0.8 m and 1.2 m”. According to some embodiments, “about” may specify the value of a parameter to be between 90% and 110% of the given value. According to some embodiments, “about” may specify the value of a parameter to be between 95% and 105% of the given value.

As used herein, according to some embodiments, the terms “substantially” and “about” may be interchangeable.

According to some embodiments, an estimated quantity or estimated parameter may be said to be “about optimized” or “about optimal” when falling within 5%, 10%, or even 20% of the optimal value thereof. Each possibility corresponds to separate embodiments. In particular, the expressions “about optimized” and “about optimal” also cover the case wherein the estimated quantity or estimated parameter is equal to the optimal value of the quantity or the parameter. The optimal value may in principle be obtainable using mathematical optimization software. Thus, for example, an estimated (e.g., an estimated residual) may be said to be “about minimized” or “about minimal/minimum”, when the value thereof is no greater than 101%, 105%, 110%, or 120% (or some other pre-defined threshold percentage) of the optimal value of the quantity. Each possibility corresponds to separate embodiments.

For ease of description, in some of the figures a three-dimensional cartesian coordinate system (with orthogonal axes x, y, and z) is introduced. It is noted that the orientation of the coordinate system relative to a depicted object may vary from one figure to another. Further, the symbol ⊙ may be used to represent an axis pointing “out of the page”, while the symbol ⊗ may be used to represent an axis pointing “into the page”.

In block diagrams dotted lines connecting elements may be used to represent functional association or at least one-way or two-way communicational association between the connected elements.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. No feature described in the context of an embodiment is to be considered an essential feature of that embodiment, unless explicitly specified as such.

Although operations of methods, according to some embodiments, may be described in a specific sequence, the methods of the disclosure may include some or all of the described operations carried out in a different order. In particular, it is to be understood that the order of operations and suboperations of any of the described methods may be reordered unless the context clearly dictates otherwise, for example, when a latter operation requires as input the output of earlier operation or when a latter operation requires the product of an earlier operation. A method of the disclosure may include a few of the operations described or all of the operations described. No particular operation in a disclosed method is to be considered an essential operation of that method, unless explicitly specified as such.

Although the disclosure is described in conjunction with specific embodiments thereof, it is evident that numerous alternatives, modifications, and variations that are apparent to those skilled in the art may exist. Accordingly, the disclosure embraces all such alternatives, modifications, and variations that fall within the scope of the appended claims. It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purpose and should not be regarded as limiting. Citation or identification of any reference in this application shall not be construed as an admission that such reference is available as prior art to the disclosure. Section headings are used herein to ease understanding of the specification and should not be construed as necessarily limiting.

What is claimed is:

1. A system for non-destructive depth-profiling of samples, the system comprising:
an electron beam (e-beam) source for projecting e-beams at each of a plurality of landing energies on an inspected sample;
an electron sensor for obtaining a measured set of electron intensities pertaining to each of the landing energies; and
processing circuitry for determining a set of structural parameters, which characterizes an internal geometry and/or a composition of the inspected sample, based on the measured set of electron intensities and taking into account reference data indicative of an intended design of the inspected sample.

2. The system of claim 1, wherein each of the e-beams is configured to penetrate the inspected sample to a respective depth, determined by the respective landing energy, such that the inspected sample is probed over a desired range of depths.

3. The system of claim 1, wherein the reference data comprise design data of the inspected sample and/or ground truth (GT) data of other samples of the same intended design as the inspected sample and/or GT data of especially prepared samples exhibiting selected variations with respect to the intended design.

4. The system of claim 1, wherein the set of structural parameters specifies one or more concentration maps quantifying a dependence of one or more concentrations of one or more substances, respectively, which the inspected sample comprises, at least on the depth.

5. The system of claim 1, wherein the set of structural parameters comprises one or more of:
one or more overall concentrations of one or more substances, respectively, that the inspected sample comprises; and
at least one width of at least one structure, respectively, which is embedded in the inspected sample; and/or
when the inspected sample comprises a plurality of layers, one or more of:
at least one thickness of at least one of the plurality of layers, respectively;
a combined thickness of at least some of the plurality of layers; and
at least one mass density of at least one of the plurality of layers, respectively.

6. The system of claim 4, further configured to allow projecting the e-beams so as to impinge on the inspected sample at each of controllably selectable lateral locations thereon;
wherein the concentration map is three-dimensional; and
wherein the processing circuitry is configured to, in generating the concentration map, take into account measured sets of electron intensities obtained by the electron sensor for each of the lateral locations.

7. The system of claim 1, wherein the electron sensor is configured to sense electrons returned from the inspected sample, thereby obtaining the measured set of electron intensities.

8. The system of claim 1, wherein, in order to determine the set of structural parameters, the processing circuitry is configured to execute a trained algorithm, which is configured to receive as an input the measured set of electron intensities either raw or following initial processing by the processing circuitry; and
wherein the initial processing of the measured set of electron intensities comprises isolating, or at least amplifying, contributions to the raw measured set of electron intensities of backscattered electrons induced by the projected e-beams.

9. The system of claim 8, wherein weights of the trained algorithm are determined through training using the reference data and (i) measured sets of electron intensities of other samples of the same intended design as the inspected sample, and/or (ii) simulated sets of electron intensities obtained by simulating impinging of samples of the same intended design as the inspected sample with e-beams at each of a plurality of landing energies.

10. The system of claim 8, wherein the trained algorithm is or comprises a neural network, or wherein the trained algorithm is or comprises a linear model-incorporating algorithm.

11. The system of claim 8, wherein the set of structural parameters specifies a concentration map specifying at each map coordinate (i) a substance, having a highest density about the map coordinate, out of a plurality of substances, which the inspected sample comprises, and/or (ii) a density of a target substance, which the inspected sample comprises, to within a respective density range from a plurality of density ranges; and
wherein the trained algorithm is or comprises a classification neural network.

12. A computer-based method for non-destructive depth-profiling of samples, the method comprising:
a measurement operation comprising obtaining a measured set of electron intensities by performing, for each of a plurality of landing energies, selected so as to allow probing an inspected sample to a plurality of depths, suboperations of:
projecting an electron beam (e-beam) on the inspected sample, which penetrates the inspected sample and induces scattering of electrons from a respective volume thereof determined by the landing energy; and
measuring an electron intensity by sensing backscattered electrons returned from the inspected sample; and
a data analysis operation comprising determining a set of structural parameters, which characterizes an internal geometry and/or a composition of the inspected sample, based on the measured set of electron intensities and taking into account reference data indicative of an intended design of the inspected sample.

13. The method of claim 12, wherein the reference data comprise design data of the inspected sample and/or ground truth (GT) data of other samples of the same intended design as the inspected sample and/or GT data of especially prepared samples exhibiting selected variations with respect to the intended design.

14. The method of claim 12, wherein the set of structural parameters specifies a concentration map quantifying a dependence of a concentration of a target substance, which the inspected sample comprises, at least on the depth.

15. The method of claim 12, wherein the set of structural parameters comprises one or more of:
one or more overall concentrations of one or more substances, respectively, that the inspected sample comprises; and
at least one width of at least one structure, respectively, which is embedded in the inspected sample; and/or
when the inspected sample comprises a plurality of layers, one or more of:
at least one thickness of at least one of the plurality of layers, respectively;
a combined thickness of at least some of the plurality of layers; and
at least one mass density of at least one of the plurality of layers, respectively.

16. The method of claim 14, wherein, in the measurement operation, the e-beams are projected so as to impinge on the inspected sample at each of controllably selectable lateral locations thereon;
wherein the concentration map is three-dimensional; and
wherein, in the data analysis operation, the concentration map is generated taking into account measured sets of electrons intensities, which are obtained for each of the lateral locations, respectively.

17. The method of claim 12, wherein, in the data analysis operation, in order to determine the set of structural parameters, executed is a trained algorithm, which is configured to receive as an input the measured set of electron intensities, either raw or following initial processing, which comprises isolating, or at least amplifying, contributions to the raw measured set of electron intensities of the backscattered electrons induced by the projected e-beams.

18. The method of claim 17, wherein weights of the trained algorithm are determined through training using the reference data and (i) measured sets of electron intensities of other samples of the same intended design as the inspected sample, and/or (ii) simulated sets of electron intensities obtained by simulating impinging of samples of the same intended design as the inspected sample with e-beams at each of a plurality of landing energies.

19. The method of claim 17, wherein the trained algorithm is or comprises a neural network, or wherein the trained algorithm is or comprises a linear model-incorporating algorithm.

20. The method of claim 17, wherein the set of structural parameters specifies a concentration map specifying at each map coordinate (i) a substance, having a highest density about the map coordinate, out of a plurality of substances, which the sample comprises, and/or (ii) a density of a target substance, which the sample comprises, to within a respective density range from a plurality of density ranges; and
wherein the trained algorithm is or comprises a classification neural network.
